(19) United States
(12) Patent Application Publication
(10) Pub. No.: US 2014/0021608 A1
(43) Pub. Date: Jan. 23, 2014

(54) SEMICONDUCTOR PACKAGE AND METHOD OF FABRICATING THE SAME

(71) Applicant: SAMSUNUNG ELECTRONICS., LTD., Suwon-si (KR)

(72) Inventor: KEUN-HO CHOI, Asan-si (KR)

(73) Assignee: Samsunung Electronics., Ltd., Suwon-si (KR)

(21) Appl. No.: 13/887,542

(22) Filed: May 6, 2013

(30) Foreign Application Priority Data
Jul. 18, 2012 (KR) 10-2012-0078397

(51) Int. Cl. H01L 23/498; H01L 21/56

(52) U.S. Cl. CPC H01L 23/49816; H01L 21/56
USPC 257/738; 438/127

(57) ABSTRACT

A semiconductor package includes a first semiconductor chip including a first chip pad located on an upper surface thereof, a second semiconductor chip offset-stacked on the upper surface of the first semiconductor chip and including a second chip pad located on an upper surface thereof, a chip coupling ball located on a first board pad of the first semiconductor chip, a chip coupling bump located on a second board pad of the second semiconductor chip, and a chip connection wire connecting the chip coupling ball and the chip coupling bump. The chip connection wire has a chip connection curve part with a reverse curve shape.

### CROSS-REFERENCE TO RELATED APPLICATION

This application claims priority under 35 U.S.C. §119 to Korean Patent Application No. 10-2012-0078397 filed on Jul. 18, 2012, the disclosure of which is hereby incorporated by reference in its entirety.

### BACKGROUND

1. Technical Field

Embodiments of the inventive concept relate to a semiconductor package in which a wire connects two offset-stacked semiconductor chips, and a method of fabricating the same.

2. Discussion of Related Art

A semiconductor package may include a circuit board and semiconductor chips stacked on the circuit board. The semiconductor chips may be, for example, offset-stacked on the circuit board. Two adjacent semiconductor chips among the offset-stacked semiconductor chips may be connected by chip bonding structures. The chip bonding structures may include, for example, a wire including a loop of a certain height. Various studies have been conducted on the semiconductor package to reduce the loop of the wire.

### SUMMARY

Exemplary embodiments of the inventive concept provide a semiconductor package including a relatively small vertical distance between the lowest level and the highest level of a chip bonding structure connecting two offset-stacked semiconductor chips.

Exemplary embodiments of the inventive concept provide a method of fabricating a semiconductor package capable of lowering a wire loop of a chip bonding structure connecting two offset-stacked semiconductor chips.

In accordance with an exemplary embodiment of the inventive concept, a semiconductor package includes a first semiconductor chip including a first chip pad located on an upper surface thereof, a second semiconductor chip offset-stacked on the upper surface of the first semiconductor chip and including a second chip pad located on an upper surface thereof, a chip coupling ball located on the first chip pad of the first semiconductor chip, a chip coupling bump located on the second chip pad of the second semiconductor chip, and a chip connection wire connecting the chip coupling ball and the chip coupling bump. The chip connection wire includes a chip connection curve part located near to the chip coupling ball and including a reverse curve shape.

In an embodiment, the chip connection curve part may include a first curve region located near to the chip coupling ball, and a second curve region located near to the chip coupling bump. The first curve region may have a gradient increasing along a direction from the chip coupling ball toward the chip coupling bump. The second curve region may have a gradient decreasing along a direction from the chip coupling ball toward the chip coupling bump.

In an embodiment, the chip connection wire may further include a chip coupling neck part in contact with an upper surface of the chip coupling ball, the chip coupling neck part including a first side heading to the chip coupling bump and a second side opposite the first side. The first curve region of the chip connection curve part may be in contact with the first side of the chip coupling neck part.

In an embodiment, an upper surface of the chip coupling neck part may have a concave shape.

In an embodiment, the chip coupling bump may include a first side and a second side opposite the first side, and the second side heading to the chip coupling ball. The highest level of the first side of the chip coupling bump may be higher than the highest level of the second side of the chip coupling bump.

In an embodiment, the chip connection wire may further include a chip coupling stitch part in contact with an upper surface of the chip coupling bump, and a chip connection middle part located between the chip connection curve part and the chip coupling stitch part. The thickness of the chip coupling stitch part may decrease along a direction from the second side of the chip coupling bump toward the first side of the chip coupling bump.

In an embodiment, the chip coupling stitch part may include a chip coupling stitch groove located on an upper surface thereof.

In an embodiment, the lowest level of the chip coupling stitch groove may be higher than the highest level of the second side of the chip coupling bump, and lower than the highest level of the first side of the chip coupling bump.

In an embodiment, the chip connection middle part may include a middle region parallel to the upper surface of the second semiconductor chip.

In accordance with an exemplary embodiment of the inventive concept, a semiconductor package includes a circuit board including a first board pad located on an upper surface thereof, a first semiconductor chip mounted on the upper surface of the circuit board and including a first chip pad located on an upper surface thereof, a second semiconductor chip offset-stacked on the upper surface of the first semiconductor chip and including a second chip pad located on an upper surface thereof, a first board bonding structure connecting the first board pad and the first chip pad, and a first chip bonding structure connecting the first chip pad and the second chip pad. A vertical distance between a lowest level and a highest level of the first chip bonding structure is smaller than a vertical distance between a lowest level and a highest level of the first board bonding structure.

In an embodiment, the first board bonding structure may include a board coupling ball located on the first board pad, a board coupling bump located on the first chip pad, and a board connection wire connecting the board coupling ball and the board coupling bump. The first chip bonding structure may include a chip coupling ball located on the first chip pad, a chip coupling bump located on the second chip pad, and a chip connection wire connecting the chip coupling ball and the chip coupling bump. The board coupling bump may be located between the first chip pad and the first chip coupling ball.

In an embodiment, the chip connection wire may include a chip coupling neck part in contact with an upper surface of the chip coupling ball, a chip coupling stitch part in contact with an upper surface of the chip coupling bump, a chip connection curve part located near to the chip coupling neck part, and a chip connection middle part located between the chip connection curve part and the chip coupling stitch part. The chip connection curve part may have a logistic curve shape.

In an embodiment, a level difference of an upper surface of the board coupling bump may be smaller than that of the chip coupling bump.

In an embodiment, the semiconductor package may further include a third semiconductor chip offset-stacked on the upper surface of the second semiconductor chip and including a third chip pad located on an upper surface thereof, a fourth semiconductor chip offset-stacked on the upper surface of the third semiconductor chip and including a fourth chip pad located on an upper surface thereof, a second board bonding structure connecting the third chip pad and a second board pad of the circuit board, and a second chip bonding structure connecting the third chip pad and the fourth chip pad. A vertical distance between the lowest level and the highest level of the second chip pad may be the same as that of the first chip bonding structure.

In an embodiment, the third semiconductor chip may be vertically aligned with the first semiconductor chip. The fourth semiconductor chip may be vertically aligned with the second semiconductor chip. A vertical distance between the second semiconductor chip and the third semiconductor chip may be greater than that between the first semiconductor chip and the second semiconductor chip.

In accordance with an exemplary embodiment of the inventive concept, a method for fabricating a semiconductor package is provided. The method includes providing a circuit board including a first board pad disposed on an upper surface thereof, mounting a first semiconductor chip on the upper surface of the circuit board such that the first semiconductor chip does not overlap with the first board pad, the first semiconductor chip including a first chip pad disposed on an upper surface thereof, off-set stacking a second semiconductor chip on the upper surface of the first semiconductor chip such that a part of the upper surface of the first semiconductor chip is exposed and the second semiconductor chip does not overlap with the first chip pad, the second semiconductor chip including a second chip pad disposed on an upper surface thereof, forming a first board coupling bump on the upper surface of the first chip pad and a first chip coupling bump on an upper surface of the second chip pad, mounting the first board coupling ball on an upper surface of the first board pad, forming a first board connection wire connecting the first board coupling bump and the first board coupling ball. The first board connection wire includes a first board connection stitch part located on an upper surface of the first board coupling bump, and the first connection stitch part includes a groove located in an upper surface thereof.

In addition, the method further includes mounting the first chip coupling ball on an upper surface of the first chip pad and in the groove of the first board connection stitch part, forming a first chip coupling neck part on an upper surface of the first chip coupling ball, forming a first chip connection curve part extending from a first side of the first coupling neck part toward the first chip coupling bump, forming a first connection wire connecting the first chip coupling bump and the first chip coupling ball and forming a molding substance on an upper surface of the circuit board and covering the first semiconductor chip and the second semiconductor chip.

### BRIEF DESCRIPTION OF THE DRAWINGS

Exemplary embodiments of the inventive concept can be understood in more detail from the following detailed description taken in conjunction with the attached drawings in which;

FIG. 1A is a cross-sectional view illustrating a semiconductor package in accordance with an embodiment of the inventive concept;

FIG. 1B is an enlarged partial view illustrating region P in FIG. 1A;

FIG. 1C is an enlarged partial view illustrating region Q in FIG. 1A;

FIG. 1D is an enlarged partial view illustrating region R in FIG. 1A;

FIG. 2 is a partial view illustrating a first bonding structure of a semiconductor package in accordance with an embodiment of the inventive concept;

FIG. 3 is a partial view illustrating a first chip bonding structure of a semiconductor package in accordance with an embodiment of the inventive concept;

FIG. 4A is a cross-sectional view illustrating a semiconductor package in accordance with an embodiment of the inventive concept;

FIG. 4B is an enlarged partial view illustrating region S in FIG. 4A;

FIG. 5A is a cross-sectional view illustrating a semiconductor package in accordance with an embodiment of the inventive concept;

FIG. 5B is an enlarged partial view illustrating region T in FIG. 5A;

FIG. 6A is a cross-sectional view illustrating a semiconductor package in accordance with an embodiment of the inventive concept;

FIG. 6B is an enlarged partial view illustrating region U in FIG. 6A;

FIGS. 7A to 7R are cross-sectional views sequentially illustrating a method of fabricating a semiconductor package in accordance with an embodiment of the inventive concept;

FIGS. 8A to 8C are cross-sectional views sequentially illustrating a method of fabricating a semiconductor package in accordance with an embodiment of the inventive concept;

FIG. 9 is a configuration view illustrating a semiconductor module including a semiconductor package in accordance with an embodiment of the inventive concept;

FIG. 10 is a configuration view illustrating an electronic apparatus including a semiconductor package in accordance with an embodiment of the inventive concept;

FIG. 11 is a configuration view illustrating a mobile apparatus including a semiconductor package in accordance with an embodiment of the inventive concept; and

FIG. 12 is a configuration view illustrating a electronic system including a semiconductor package in accordance with an embodiment of the inventive concept.

### DETAILED DESCRIPTION OF EXEMPLARY EMBODIMENTS

Various exemplary embodiments will now be described more fully with reference to the accompanying drawings in which some embodiments are shown. Exemplary embodiments of the inventive concepts may, however, be embodied in different forms and should not be construed as limited to the embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

### Embodiments

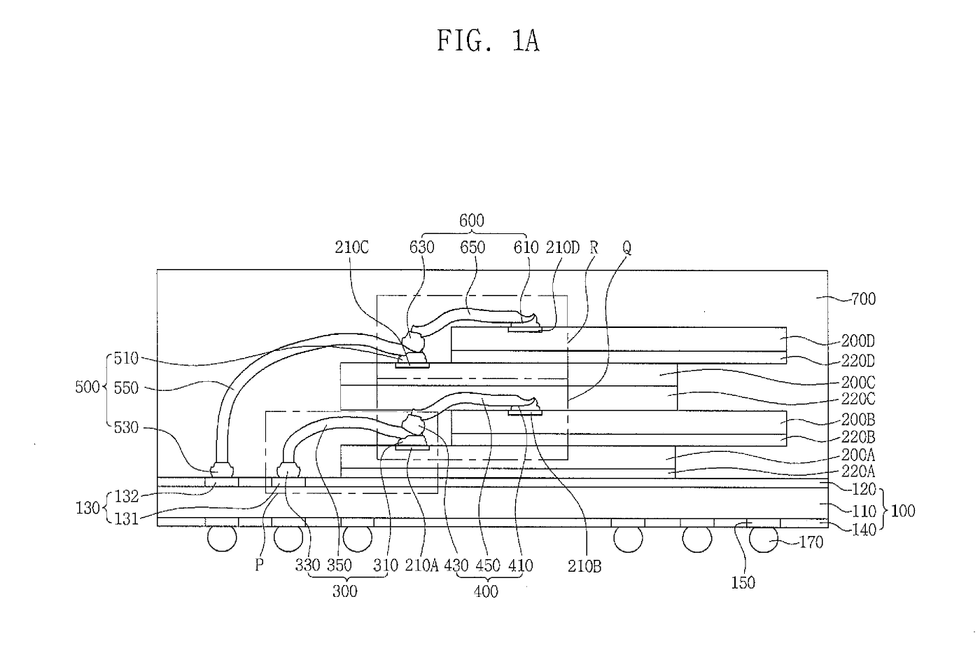

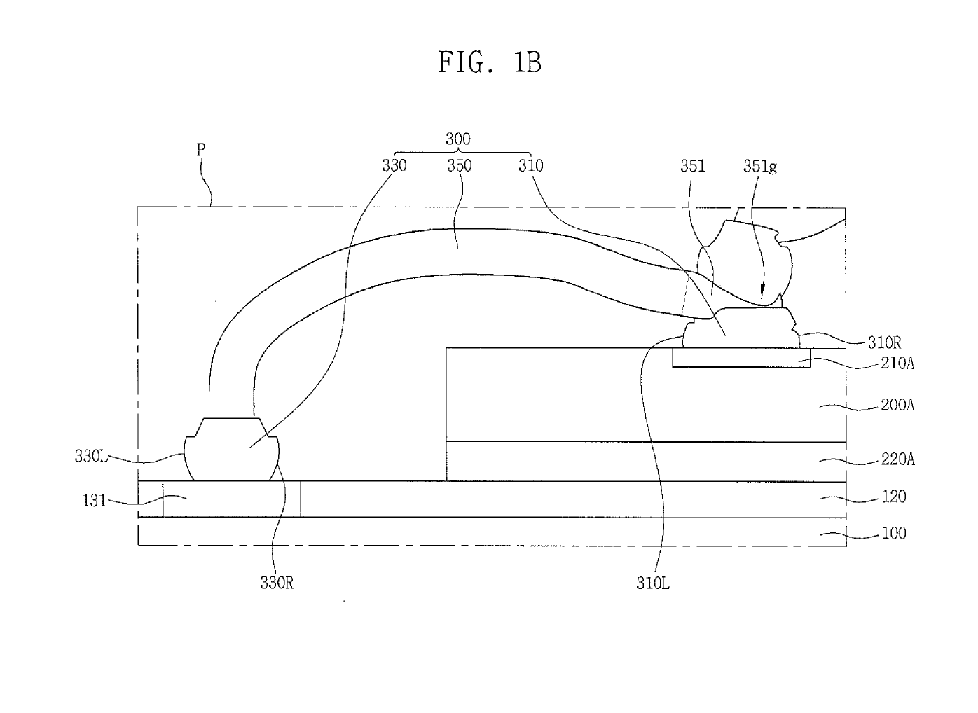

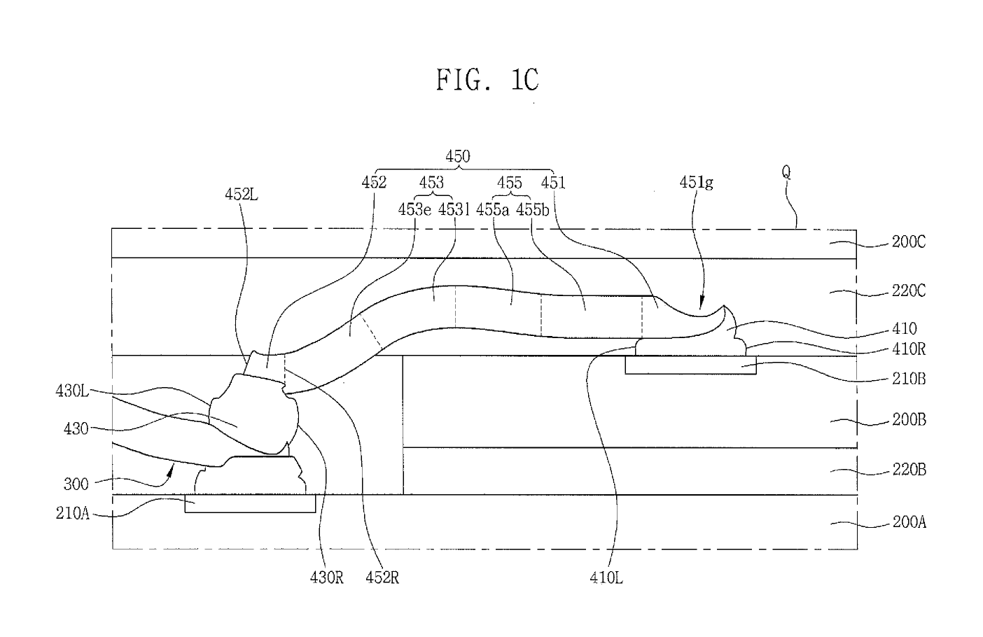

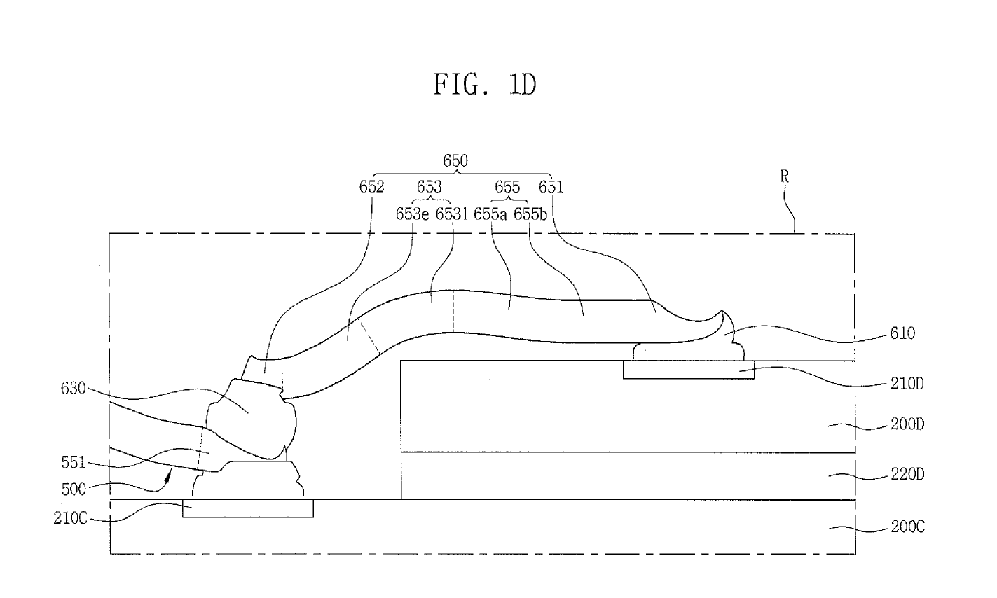

FIG. 1A is a cross-sectional view illustrating a semiconductor package in accordance with an embodiment of the inventive concept. FIG. 1B is an enlarged partial view of region P in FIG. 1A. FIG. 1C is an enlarged partial view of region Q in FIG. 1A. FIG. 1D is an enlarged partial view of region R in FIG. 1A.

Referring to FIGS. 1A to 1D, a semiconductor package in accordance with an embodiment of the inventive concept may include, for example, a circuit board 100, semiconductor chips 200A to 200D, bonding structures 300 to 600, and a molding substance 700. The semiconductor chips 200A to 200D may be, for example, offset-stacked on an upper surface of the circuit board 100. The bonding structures 300 to 600 may electrically connect the semiconductor chips 200A to 200D to the circuit board 100. The molding substance 700 may, for example, cover the semiconductor chips 200A to 200D and the bonding structures 300 to 600.

The circuit board 100 may be, for example, a printed circuit board (PCB), a lead frame (LF), or a wiring substrate. The PCB may include, for example, a rigid PCB, a flexible PCB, or a rigid flexible PCB.

The circuit board 100 may include, for example, a board body 110, an upper insulating layer 120, board pads 130, a lower insulating layer 140, and terminal pads 150. The circuit board 100 may further include, for example, external terminals 170 electrically connected to the terminal pads 150.

The board body 110 may include, for example, at least one signal wire which electrically connects the board pads 130 and the terminal pads 150. For example, the board body 110 may include a plurality of signal wiring layers.

The upper insulating layer 120 may prevent unintended electrical connection between the board body 110 and the semiconductor chips 200A to 200D. The upper insulating layer 120 may be located on an upper surface of the board body 110. The upper insulating layer 120 may cover the upper surface of the board body 110. For example, the upper insulating layer 120 may include a solder resist.

The board pads 130 may be electrically connected to the semiconductor chips 200A to 200D. Each of the board pads 130 may be connected to different semiconductor chips 200A to 200D. For example, the board pads 130 may include a first board pad 131 connected to one of the semiconductor chips 200A to 200D, and a second board pad 132 connected to another one of the semiconductor chips 200A to 200D.

The board pads 130 may be located, for example, on the upper surface of the board body 110. The board pads 130 may be located on, for example, the upper surface of the circuit board 100. The board pads 130 may be defined by the upper insulating layer 120.

The board pads 130 may include, for example, a conductive material. For example, the board pads 130 may include gold (Au), silver (Ag), copper (Cu), nickel (Ni), or aluminum (Al).

The lower insulating layer 140 may prevent unintended electrical connection between the board body 110 and the external terminals 170. The lower insulating layer 140 may be located on a lower surface of the board body 110. The lower insulating layer 140 may cover the lower surface of the board body 110. The lower insulating layer 140 may include, for example, the same material as the upper insulating layer 120. For example, the lower insulating layer may include a solder resist.

The terminal pads 150 may be located, for example, on the lower surface of the board body 110. The terminal pads 150 may be located, for example, on a lower surface of the circuit board 100. The terminal pads 150 may be defined by the lower insulating layer 140.

The terminal pads 150 may include, for example, a conductive material. For example, the terminal pads 150 may include Au, Ag, Cu, Ni, or Al. The terminal pads 150 may include, for example, the same material as the board pads 130.

The external terminals 170 may be located, for example, on a lower surface of the terminal pads 150. The external terminals 170 may be in contact with the lower surface of the terminal pads 150. The external terminals 170 may include, for example, a solder ball, a solder bump, a grid array, or a conductive tab.

The semiconductor chips 200A to 200D may include, for example, a dynamic random access memory chip (DRAM), a flash memory chip, or a variable resistance memory chip. The semiconductor chips 200A to 200D may be, for example, the same kind of chips as one another. Horizontal distances between the semiconductor chips 200A to 200D may be, for example, the same as each other. The horizontal distance may imply a linear distance in a direction parallel to the upper surface of the circuit board 100.

The semiconductor chips 200A to 200D may, for example, not overlap the board pads 130. For example, the board pads 130 may be located more to the left than the left side of the semiconductor chips 200A to 200D. The left direction may be determined on the basis of the semiconductor package illustrated in FIG. 1A.

The semiconductor chips 200A to 200D may include, for example, a first semiconductor chip 200A, a second semiconductor chip 200B, a third semiconductor chip 200C, and a fourth semiconductor chip 200D. The first semiconductor chip 200A may be mounted, for example, on the upper surface of the circuit board 100. The second semiconductor chip 20013 may be, for example, offset-stacked on an upper surface of the first semiconductor chip 200A. A part of the first semiconductor chip 200A may, for example, not be overlapped with the second semiconductor chip 200B. A part of the upper surface of the first semiconductor chip 200A may be, for example, exposed by the second semiconductor chip 200B. The third semiconductor chip 200C may be, for example, offset-stacked on an upper surface of the second semiconductor chip 200B. A part of the upper surface of the second semiconductor chip 200B may, for example, not be overlapped with the third semiconductor chip 200C. A part the upper surface of the second semiconductor chip 200A may, for example, be exposed by the third semiconductor chip 200C. The fourth semiconductor chip 200D may be, for example, offset-stacked on an upper surface of the third semiconductor chip 200C. A part of the upper surface of the third semiconductor chip 200C may, for example, not be overlapped with the fourth semiconductor chip 200D. A part of the upper surface of the third semiconductor chip 200C may be, for example, exposed by the fourth semiconductor chip 200D.

For example in a semiconductor package in accordance with an embodiment of the inventive concept, four semiconductor chips 200A to 200D are stacked on the upper surface of the circuit board 100. However, the semiconductor package in accordance with an embodiment of the inventive concept may have, for example, at least two semiconductor chips stacked on the upper surface of the circuit board 100. For example, the semiconductor package in accordance with an embodiment of the inventive concept may have a power-of-two number (for example, 2, 4, 8, 16, 32, etc.) of semiconductor chips stacked on the upper surface of the circuit board 100.

The semiconductor chips 200A to 200D may be, for example, cross-stacked. For example, a part of the left side of the upper surface of the first semiconductor chip 200A may be exposed by the second semiconductor chip 200B. A part of the right side of the upper surface of the second semiconductor chip 200B may be, for example, exposed by the third semiconductor chip 200C. A part of the left side of the upper surface of the third semiconductor chip 200C may be, for example, exposed by the fourth semiconductor chip 200D.

The third semiconductor chip 200C may be, for example, vertically aligned with the first semiconductor chip 200A. The fourth semiconductor chip 200D may be, for example, vertically aligned with the second semiconductor chip 200B. The upper surface of the first semiconductor chip 200A exposed by the second semiconductor chip 200B may be, for example, vertically aligned with the upper surface of the third semiconductor chip 200C exposed by the fourth semiconductor chip 200D.

Each of the semiconductor chips 200A to 200D may include, for example, chip pads 210A to 210D located on the upper surface thereof. For example, the first semiconductor chip 200A may include a first chip pad 210A located on the upper surface thereof. The second semiconductor chip 200B may include, for example, a second chip pad 210B located on the upper surface thereof. The third semiconductor chip 200C may include, for example, a third chip pad 210C located on the upper surface thereof. The fourth semiconductor chip 200D may include, for example, a fourth chip pad 210D located on the upper surface thereof.

Each of the chip pads 210A to 210D may be located, for example, on the same region of the corresponding semiconductor chips 200A to 200D. For example, the first chip pad 210A may be located on a left upper surface of the first semiconductor chip 200A. The second chip pad 210B may be located, for example, on a left upper surface of the second semiconductor chip 200B. The third chip pad 210C may be located, for example, on a left upper surface of the third semiconductor chip 200C. The fourth chip pad 210D may be located, for example, on a left upper surface of the fourth semiconductor chip 200D.

The third chip pad 210C may be, for example, vertically aligned with the first chip pad 210A. The fourth chip pad 210D may be, for example, vertically aligned with the second chip pad 210B. For example, a horizontal distance between the left side of the first semiconductor chip 200A and the first chip pad 210A may be the same as a horizontal distance between the left side of the second semiconductor chip 200B and the second chip pad 210B. The horizontal distance between the left side of the second semiconductor chip 200B and the second chip pad 210B may be, for example, the same as a horizontal distance between the left side of the third semiconductor chip 200C and the third chip pad 210C. The horizontal distance between the left side of the third semiconductor chip 200C and the third chip pad 210C may be, for example, the same as a horizontal distance between the left side of the fourth semiconductor chip 200D and the fourth chip pad 210D.

The first chip pad 210A may be located, for example, on the upper surface of the first semiconductor chip 200A exposed by the second semiconductor chips 200B. The second chip pad 210B may be located, for example, on the upper surface of the second semiconductor chip 200B overlapped with the third semiconductor chip 200C. The third chip pad 210C may be located, for example, on the upper surface of the third semiconductor chip 200C exposed by the fourth semiconductor chip 200D. The fourth chip pad 210D may be located, for example, on the upper surface of the fourth semiconductor chip 200D overlapping the third semiconductor chip 200C. The first chip pad 210A and the third chip pad 210C may be, for example, connected to the board pads 130. For example, the first chip pad 210A may be connected to the first board pad 131. The third chip pad 210C may be connected to the second board pad 132.

The second chip pad 210B may be connected to, for example, the first board pad 131 through the first chip pad 210A. For example, the second chip pad 210B may be connected to the first chip pad 210A.

The fourth chip pad 210D may be connected to, for example, the second board pad 132 through the third chip pad 210C. For example, the fourth chip pad 210D may be connected to the third chip pad 210C.

The chip pads 210A to 210D may include, for example, a conductive material. For example, the chip pads 210A to 210D may include Au, Ag, Cu, Ni, or Al. The chip pads 210A to 210D may include, for example, the same material as the board pads 130.

A semiconductor package in accordance with an embodiment of the inventive concept may further include, for example, adhesive layers 220A to 220D located on lower surfaces of the semiconductor chips 200A to 200D, respectively. The adhesive layers 220A to 220D may include, for example, a first adhesive layer 220A, a second adhesive layer 220B, a third adhesive layer 220C, and a fourth adhesive layer 220D. For example, the first adhesive layer 220A may be located on a lower surface of the first semiconductor chip 200A. The second adhesive layer 22013 may be located, for example, on a lower surface of the second semiconductor chip 200B. The third adhesive layer 220C may be located, for example, on a lower surface of the third semiconductor chip 200C. The third adhesive layer 220C may cover the second chip pad 210B. An upper surface of the second chip pad 210B may be, for example, in direct contact with the third adhesive layer 220C. The fourth adhesive layer 220D may be located, for example, on a lower surface of the fourth semiconductor chip 200D.

The thickness of the first adhesive layer 220A may be, for example, the same as a vertical distance between the circuit board 100 and the first semiconductor chip 200A. The thickness of the second adhesive layer 220B may be, for example, the same as a vertical distance between the first semiconductor chip 200A and the second semiconductor chip 200B. The thickness of the third adhesive layer 220C may be, for example, the same as a vertical distance between the second semiconductor chip 200B and the third semiconductor chip 200C. The thickness of the fourth adhesive layer 220D may be, for example, the same as a vertical distance between the third semiconductor chip 200C and the fourth semiconductor chip 200D. The vertical distance may imply a linear distance in a direction perpendicular to the upper surface of the circuit board 100.

The thickness of the second adhesive layer 220B may be, for example, the same as the thickness of the first adhesive layer 220A. The vertical distance between the circuit board 100 and the first semiconductor chip 200A is, for example, the same as the vertical distance between the first semiconductor chip 200A and the second semiconductor chip 200B. The thickness of the third adhesive layer 220C may be, for example, greater than the thickness of the second adhesive layer 220B. The vertical distance between the second semiconductor chip 200B and the third semiconductor chip 200C may be, for example, greater than the vertical distance between the first semiconductor chip 200A and the second semiconductor chip 200B. The thickness of the fourth adhesive layer 220D may be, for example, the same as the thickness of the second adhesive layer 220B. The vertical distance between the third semiconductor chip 200C and the fourth semiconductor chip 200D may be, for example, the same as the vertical distance between the first semiconductor chip 200A and the second semiconductor chip 200B.

The adhesive layers 220A to 220D may include, for example, an epoxy resin. For example, the adhesive layers 220A to 220D may include a die attach film (DAF).

The third adhesive layer 220C may be, for example, softer than the first, second, and fourth adhesive layers 220A, 220B, and 220D. For example, the first, second, and fourth adhesive layers 220A, 220B, and 220D may have higher density the density of the third adhesive layer 220C.

The bonding structures 300 to 600 may, for example, electrically connect the chip pads 210A to 210D to the board pads 130. The bonding structures 300 to 600 may include, for example, board bonding structures 300 and 500 which connect the board pads 130 and the chip pads 210A to 210D, and chip bonding structures 400 and 600 which connect the chip pads 210A to 210D to each other. For example, the bonding structures 300 to 600 may include a first board bonding structure 300 connecting the first board pads 131 and the first chip pad 210A, a first chip bonding structure 400 connecting the first chip pad 210A and the second chip pad 210B, a second board bonding structure 500 connecting the second board pad 132 and the third chip pad 210C, and a second chip bonding structure 600 connecting the third chip pad 210C and the fourth chip pad 210D.

The first board bonding structures 300 may include, for example, a first board coupling bump 310, a first board coupling ball 330, and a first board connection wire 350. The first board coupling bump 310 may be located, for example, on an upper surface of the first chip pad 210A. The first board coupling ball 330 may be located, for example, on an upper surface of the first board pad 131. The first board connection wire 350 may connect, for example, the first board coupling bump 310 and the first board coupling ball 330.

The first board coupling bump 310 may be, for example, in direct contact with the upper surface of the first chip pad 210A. The first board coupling bump 310 may include, for example, a first side 310R and a second side 310L. The second side 310L of the first board coupling bump 310 may be, for example, opposite the first side 310R of the first board coupling bump 310. For example, the first side 310R of the first board coupling bump 310 may be a right side of the first board coupling bump 310. The second side 310L of the first board coupling bump 310 may be, for example, a left side of the first board coupling bump 310. The first side 310R of the first board coupling bump 310 may, for example, head to the second semiconductor chip 200B. The first side 310R of the first board coupling bump 310 may, for example, face the left side of the second semiconductor chip 200B. The second side 310L of the first board coupling bump 310 may, for example, head to the first board coupling ball 330. The highest level of the second side 310L of the first board coupling bump 310 may be lower than the highest level of the first side 310R of the first board coupling bump 310.

The first board coupling ball 330 may be, for example, in direct contact with the upper surface of the first board pad 131. The first board coupling ball 330 may include, for example, a first side 330R and a second side 330L. The second side 330L of the first board coupling ball 330 may be, for example, opposite the first side 330R of the first board coupling ball 330. The first side 330R of the first board coupling ball 330 may, for example, face the second side 310L of the first board coupling bump 310. The highest level of the first side 330R of the first board coupling ball 330 may be, for example, the same as the highest level of the second side 330L of the first board coupling ball 330. The second side 330L of the first board coupling ball 330 may be, for example, symmetrical to the first side 330R of the first board coupling ball 330.

The first board connection wire 350 may be, for example, in direct contact with an upper surface of the first board coupling ball 330. The first board connection wire 350 may extend, for example, in an upward direction of the first board coupling ball 330. The first board connection wire 350 may have, for example, a convex shape with respect to the upper surface of the circuit board 100.

The first board connection wire 350 may include, for example, a first board connection stitch part 351 located on an upper surface of the first board coupling bump 310. The first board connection stitch part 351 may be, for example, in direct contact with the upper surface of the first board coupling bump 310. The thickness of the first board connection stitch part 351 may, for example, gradually become thinner toward the first side 310R from the second side 310L of the first board coupling bump 310.

An upper surface of the first board connection stitch part 351 may have, for example, a concave shape with respect to the upper surface of the circuit board 100. The first board connection stitch part 351 may include, for example, a first board coupling stitch groove 351g located on the upper surface thereof. The lowest level of the first board coupling stitch groove 351g may be, for example, higher than the highest level of the first side 310R of the first board coupling bump 310. The lowest level of the first board coupling stitch groove 351g may be, for example, higher than the highest level of the second side 310L of the first board coupling bump 310.

The first chip bonding structure 400 may include, for example, a first chip coupling bump 410, a first chip coupling ball 430, and a first chip connection wire 450. The first chip coupling bump 410 may be located, for example, on the upper surface of the second chip pad 21013. The first chip coupling ball 430 may be located, for example, on the upper surface of the first chip pad 210A. The first chip connection wire 450 may, for example, connect the first chip coupling bump 410 and the first chip coupling ball 430.

The first chip coupling bump 410 may be, for example, in direct contact with the upper surface of the second chip pad 210B. The first chip coupling bump 410 may include, for example, a first side 410R and a second side 410L. The second side 410L of the first chip coupling bump 410 may be, for example, opposite the first side 410R of the first chip coupling bump 410. The second side 410L of the first chip coupling bump 410 may, for example, face the first side 410R of the first chip coupling bump 410. The highest level of the first side 410R of the first chip coupling bump 410 may be, for example, higher than the highest level of the second side 410L of the first chip coupling bump 410.

A linear distance between the highest level of the first side 410R and the highest level of the second side 410L of the first chip coupling bump 410 may be, for example, higher than a linear distance between the highest level of the first side 310R and the highest level of the second side 310L of the first board coupling bump 310. A level difference of an upper surface of the first chip coupling bump 410 may be, for example, greater than that of the first board coupling bump 310.

The first chip coupling ball 430 may be located, for example, on the upper surface of the first board coupling bump 310. The first chip coupling ball 430 may be, for example, in contact with the upper surface of the first board connection stitch part 351 of the first board connection wire 350. The first chip coupling ball 430 may, for example, fill the first board coupling stitch groove 351g of the first board connection stitch part 351.

The first chip coupling ball 430 may include, for example, a first side 430R and a second side 430L. The second side 430L of the first chip coupling ball 430 may be, for example, opposite the first side 430R of the first chip coupling ball 430. The first side 430R of the first chip coupling ball 430 may, for example, face the second side 410L of the first chip coupling bump 410. The second side 430L of the first chip coupling ball 430 may, for example, face the first side 330R of the first board coupling ball 330. The highest level of the first side 430R of the first chip coupling ball 430 may be, for example, lower than the highest level of the second side 430L of the first chip coupling ball 430.

The first chip connection wire 450 may be located, for example, between the first chip coupling bump 410 and the first chip coupling ball 430. A part of the first chip connection wire 450 may be, for example, located on the upper surface of the second semiconductor chip 200B. The first chip connection wire 450 may, for example, pass through the third adhesive layer 220C. The third adhesive layer 220C may cover, for example, a part of the first chip connection wire 450. The first chip connection wire 450 may be, for example, spaced apart from the lower surface of the third semiconductor chip 200C.

The first chip connection wire 450 may include, for example, a first chip coupling stitch part 451, a first chip coupling neck part 452, a first chip connection curve part 453, and a first chip connection middle part 455. The first chip connection curve part 453 may be, for example, located near to the first chip coupling neck part 452. The first chip connection curve part 453 may be, for example, extended from the first chip coupling neck part 452. The first chip connection middle part 455 may be, for example, located between the first chip connection curve part 453 and the first chip coupling stitch part 451.

The first chip coupling stitch part 451 may be, for example, in direct contact with the upper surface of the first chip coupling bump 410. The thickness of the first chip coupling stitch part 451 may, for example, become thinner toward the first side 410R from the second side 410L of the first chip coupling bump 410. The lowest level of the first chip coupling stitch part 451 may be, for example, the same as the highest level of second side 410L of the first chip coupling bump 410.

An upper surface of the first chip coupling stitch part 451 may have, for example, a concave shape with respect to the upper surface of the circuit board 100. The first chip coupling stitch part 451 may include, for example, a first chip coupling stitch groove 451g located on the upper surface thereof. The lowest level of the first chip coupling stitch groove 451g may be, for example, lower than the highest level of the first side 410R of the first chip coupling bump 410. The lowest level of the first chip coupling stitch groove 451g may be, for example, higher than the highest level of the second side 410L of the first chip coupling bump 410.

The first chip coupling neck part 452 may be, for example, in direct contact with an upper surface of the first chip coupling ball 430. The first chip coupling neck part 452 may include, for example, a first side 452R and a second side 452L. The second side 452L of the first chip coupling neck part 452 may be, for example, opposite the first side 452R of the first chip coupling neck part 452. The first side 452R of the first chip coupling neck part 452 may, for example, face second side 410L of the first chip coupling bump 410. The second side 452L of the first chip coupling neck part 452 may, for example, face the first side 330R of the first board coupling ball 330. The highest level of the first side 452R of the first chip coupling neck part 452 may be, for example, lower than the highest level of the second side 452L of the first chip coupling neck part 452. An upper surface of the first chip coupling neck part 452 may have, for example, a concave shape with respect to the upper surface of the circuit board 100.

The first chip connection curve part 453 may be located, for example, near to the first chip coupling ball 430. The first chip connection curve part 453 may extend, for example, from the first chip coupling neck part 452 toward the first chip coupling stitch part 451. The first chip connection curve part 453 may include, for example, a first curve region 453e and a second curve region 453l.

The first curve region 453e may be located, for example, near to the first chip coupling neck part 452. The first curve region 453e may be, for example, in direct contact with the first side 452R of the first chip coupling neck part 45. The first curve region 453e may have, for example, a curve shape in which a gradient increases from the first side 452R of the first chip coupling neck part 452 toward the first chip coupling stitch part 451. For example, the first curve region 453e may have a concave shape with respect to the upper surface of the circuit board 100. For example, the first curve region 453e may have an exponential curve shape.

The second curve region 453l may be located, for example, near to the first chip coupling stitch part 451. The second curve region 453l may be located, for example, between the first curve region 453e and the first chip coupling stitch part 451. The second curve region 453l may have, for example, a curve shape which is curved in an opposite direction to the first curve region 453e. The second curve region 453l may have, for example, a curve shape in which a gradient decreases from the first chip coupling neck part 452 toward the first chip coupling stitch part 451. For example, the second curve region 453l may have a convex shape with respect to the upper surface of the circuit board 100. For example, the second curve region 453l may have a logarithmic curve shape. A curvature of the second curve region 453l may be, for example, different from a curvature of the first curve region 453e.

The first chip connection curve part 453 may have, for example, a shape in which the first curve region 453e is connected to the second curve region 453l. The first chip connection curve part 453 may extend, for example, from the first side 452R of the first chip coupling neck part 452 toward the first chip coupling stitch part 451, and may have a curve shape in which a curve including increasing-gradient is connected to a curve including decreasing-gradient. For example, the first chip connection curve part 453 may include a concave shaped curve in direct contact with the first side 452R of the first chip coupling neck part 452 and a convex shaped curve connected to the concave shaped curve. The first chip connection curve part 453 may have, for example, a reverse curve shape. The first chip connection curve part 453 may have, for example, a shape in which an exponential curve is connected to a logarithmic curve. For example, the first chip connection curve part 453 may have a logistic curve shape.

The first chip connection middle part 455 may be, for example, located between the first chip coupling stitch part 451 and the first chip connection curve part 453. The first chip connection middle part 455 may include, for example, a first middle region 455a and a second middle region 455b.

The first middle region 455a may be, for example, located near to the first chip connection curve part 453. The first middle region 455a may, for example, connect the second curve region 453l of the first chip connection curve part 453 to the second middle region 455b. The highest level of the second curve region 453l may be, for example, higher than the highest level of the second middle region 455b. The first middle region 455a may have, for example, a falling curve shape falling from the second curve region 453l toward the second middle region 455b.

The second middle region 455b may be located near to the first chip coupling stitch part 451. The second middle region 455b may have a linear shape. For example, the second middle region 455b may be parallel to the upper surface of the second semiconductor chip 200B. The lowest level of the second middle region 455b may be, for example, the same as the highest level of the second side 410L of the first chip coupling bump 410.

In a semiconductor package in accordance with an embodiment of the inventive concept, the first chip connection wire 450 may, for example, extend from the upper surface of the first chip coupling ball 430 to a direction parallel to the upper surface of the circuit board 100. Accordingly, in a semiconductor package in accordance with an embodiment of the inventive concept, a vertical distance between the lowest level and the highest level of the first chip bonding structure 400 may be smaller than a vertical distance between the lowest level and the highest level of the first board bonding structure 300. Accordingly, in a semiconductor package in accordance with an embodiment of the inventive concept, the thickness of the third adhesive layer 220C through which the first chip connection wire 450 passes, may decrease. As a result, high density, high capacity, and a reduced size may be realized in the semiconductor package in accordance with an embodiment of the inventive concept.

The second board bonding structure 500 may include, for example, a second board coupling bump 510, a second board coupling ball 530, and a second board connection wire 550. The second board coupling bump 510 may be located, for example, on the upper surface of the third chip pad 210C. The second board coupling ball 530 may be located, for example, on an upper surface of the second board pad 132. The second board connection wire 550 may, for example, connect the second board coupling bump 510 and the second board coupling ball 530.

The second board coupling bump 510 may be, for example, in direct contact with the upper surface of the third chip pad 210C. The second board coupling bump 510 may have, for example, the same shape as the first board coupling bump 310.

The second board coupling ball 530 may be, for example, in direct contact with the upper surface of the second board pad 132. The second board coupling ball 530 may have, for example, the same shape as the first board coupling ball 330.

The second board connection wire 550 may be, for example, in direct contact with an upper surface of the second board coupling ball 530. The second board connection wire 550 may extend, for example, in an upward direction of the second board coupling ball 530. The second board connection wire 550 may have, for example, a convex shape with respect to the upper surface of the circuit board 100.

The second board connection wire 550 may include, for example, a second board connection stitch part 551 located on an upper surface of the second board coupling bump 510. The second board connection stitch part 551 may be, for example, in direct contact with the upper surface of the second board coupling bump 510. The second board connection stitch part 551 may have, for example, the same shape as the first board connection stitch part 351.

The second chip bonding structure 600 may include, for example, a second chip coupling bump 610, a second chip coupling ball 630, and a second chip connection wire 650. The second chip coupling bump 610 may be located, for example, on the upper surface of the fourth chip pad 210D. The second chip coupling ball 630 may be, for example, located on the upper surface of the third chip pad 210C. The second chip connection wire 650 may, for example, connect the second chip coupling bump 610 and the second chip coupling ball 630.

The second chip coupling bump 610 may be, for example, in direct contact with the upper surface of the fourth chip pad 210D. The second chip coupling bump 610 may have, for example, the same shape as the first chip coupling bump 410.

The second chip coupling ball 630 may be located, for example, on the upper surface of the second board coupling bump 510. The second chip coupling ball 630 may be, for example, in direct contact with an upper surface of the second board connection wire 550. The second chip coupling ball 630 may have, for example, the same shape as the first chip coupling ball 430.

The second chip connection wire 650 may include, for example, a second chip coupling stitch part 651, a second chip coupling neck part 652, a second chip connection curve part 653, and a second chip connection middle part 655. The second chip connection curve part 653 may be located, for example, near to the second chip coupling neck part 652. The second chip connection middle part 655 may be located, for example, between the second chip connection curve part 653 and the second chip connection middle part 655.

The second chip coupling stitch part 651 may be, for example, in direct contact with an upper surface of the second chip coupling bump 610. The second chip coupling stitch part 651 may have, for example, the same shape as the first chip coupling stitch part 451.

The second chip coupling neck part 652 may be, for example, in direct contact with an upper surface of the second chip coupling ball 630. The second chip coupling neck part 652 may have, for example, the same shape as the first chip coupling neck part 452.

The second chip connection curve part 653 may extend, for example, from the second chip coupling neck part 652 toward the second chip coupling stitch part 651. The second chip connection curve part 653 may include, for example, a third curve region 653e and a fourth curve region 653l. The third curve region 653e may be located, for example, near to the second chip coupling neck part 652. The fourth curve region 653l may be located, for example, near to the second chip coupling stitch part 651.

The third curve region 653e may have, for example, a gradient that increases as the distance from the second chip coupling neck part 652 increases. The third curve region 653e may have, for example, a concave shape. The third curve region 653e may have, for example, an exponential curve shape. The third curve region 653e may have, for example, the same shape as the first curve region 453e.

The fourth curve region 653l may have, for example, a gradient that decreases as the distance from the second chip coupling neck part 652 increases. The fourth curve region 653l may have, for example, a curve shape curved in an opposite direction to the third curve region 653e. The fourth curve region 653l may have, for example, a convex shape. The fourth curve region 653l may have, for example, a logarithmic shape. The fourth curve region 653l may have, for example, the same shape as the second curve region 453l.

The second chip connection curve part 653 may have, for example, a combined shape of a concave curve and a convex curve. The second chip connection curve part 653 may have, for example, a reverse curve shape. The second chip connection curve part 653 may have, for example, a combined shape of an exponential curve and a logarithmic curve. The second chip connection curve part 653 may have, for example, the same shape as the first chip connection curve part 453. For example, the second chip connection curve part 653 may have a logistic curve shape.

The second chip connection middle part 655 may include, for example, a third middle region 655a and a fourth middle region 655b. The third middle region 655a may be located, for example, near to the second chip connection curve part 653. The fourth middle region 655b may be located, for example, near to the second chip coupling stitch part 651. The third middle region 655a may be located, for example, between the second chip connection curve part 653 and the second chip coupling stitch part 651. The third middle region 655a may have, for example, a falling curve shape including a slope falling from the second chip connection curve part 653 to the second chip coupling stitch part 651. The fourth middle region 655b may have, for example, a linear shape parallel to the upper surface of the fourth semiconductor chip 200D.

The third middle region 655a may have, for example, the same shape as the first middle region 455a. The fourth middle region 655b may have, for example, the same shape as the second middle region 455b. The second chip connection middle part 655 may have, for example, the same shape as the first chip connection middle part 455.

A vertical distance between the lowest level and the highest level of the second chip bonding structure 600 may be, for example, the same as the vertical distance between the lowest level and the highest level of the first chip bonding structure 400.

Referring to a semiconductor package in accordance with an embodiment of the inventive concept, a chip bonding structure connecting two offset-stacked semiconductor chips may have a lower height than a board bonding structure connecting a circuit board and a semiconductor chip. Accordingly, in the semiconductor package in accordance with the embodiment of the inventive concept, the overall height of stacked semiconductor chips may decrease, or a relatively large number of semiconductor chips may be stacked. The semiconductor package in accordance with an embodiment of the inventive concept may have high density, high capacity, and a reduced size.

The molding substance 700 may, for example, cover the semiconductor chips 200A to 200D and the bonding structures 300 to 600. The molding substance 700 may, for example, surround the semiconductor chips 200A to 200D and the bonding structures 300 to 600. The molding substance 700 may include, for example, a thermosetting material. For example, the molding substance 700 may include an epoxy molding compound (EMC).

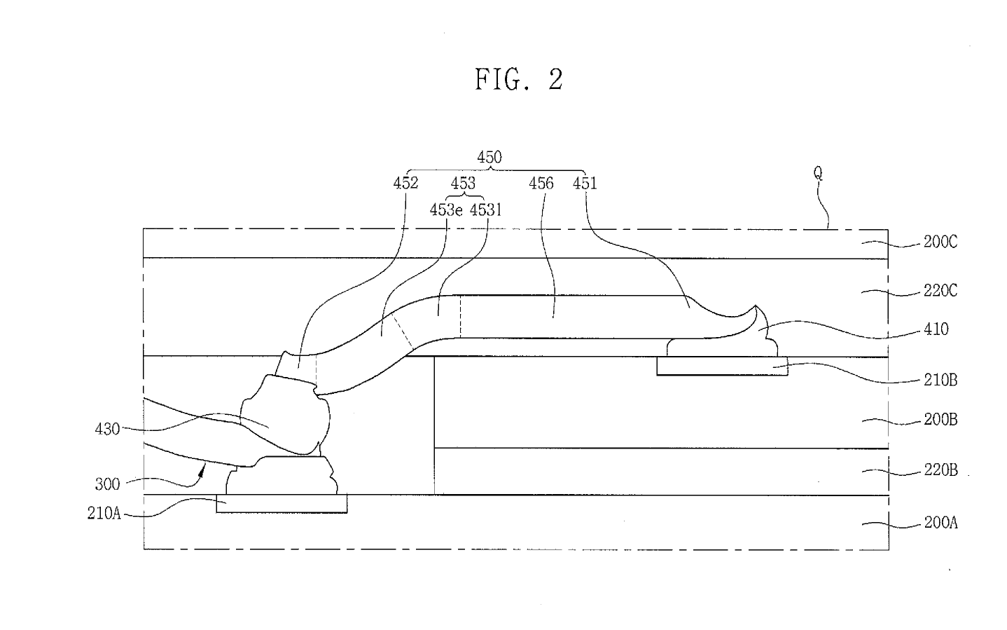

FIG. 2 is a partial view illustrating a first chip bonding structure of a semiconductor package in accordance with an embodiment of the inventive concept.

Referring to FIG. 2, the first chip bonding structure of the semiconductor package in accordance with the present embodiment of the inventive concept may include, for example, a first chip coupling bump 410 located on the upper surface of the second chip pad 210B, a first chip coupling ball 430 located on the upper surface of the first chip pad 210A, and a first chip connection wire 450 connecting the first chip coupling bump 410 and the first chip coupling ball 430.

The first chip connection wire 450 may, for example, pass through the third adhesive layer 220C. The first chip connection wire 450 may be, for example, spaced apart from the lower surface of the third semiconductor chip 200C. The first chip connection wire 450 may include, for example, a first chip coupling stitch part 451, a first chip coupling neck part 452, a first chip connection curve part 453, and a first chip connection middle part 456.

The first chip connection curve part 453 may, for example, extend from a side of the first chip coupling neck part 452 toward the first chip coupling stitch part 451. The first chip connection curve part 453 may have, for example, a reverse curve shape. The first chip connection curve part 453 may have, for example, a logistic curve shape. The first chip connection curve part 453 may include, for example, a concave-shaped first curve region 453e and a convex-shaped second curve region 453l. The first curve region 453e may be located, for example, near to the first chip coupling neck part 452.

The first chip connection middle part 456 may be located, for example, between the second curve region 453l of the first chip connection curve part 453 and the first chip coupling stitch part 451. The highest level of the second curve region 453l may be the same as the highest level of the first chip coupling stitch part 451. The first chip connection middle part 456 may be, for example, parallel to the upper surface of the second semiconductor chip 200B.

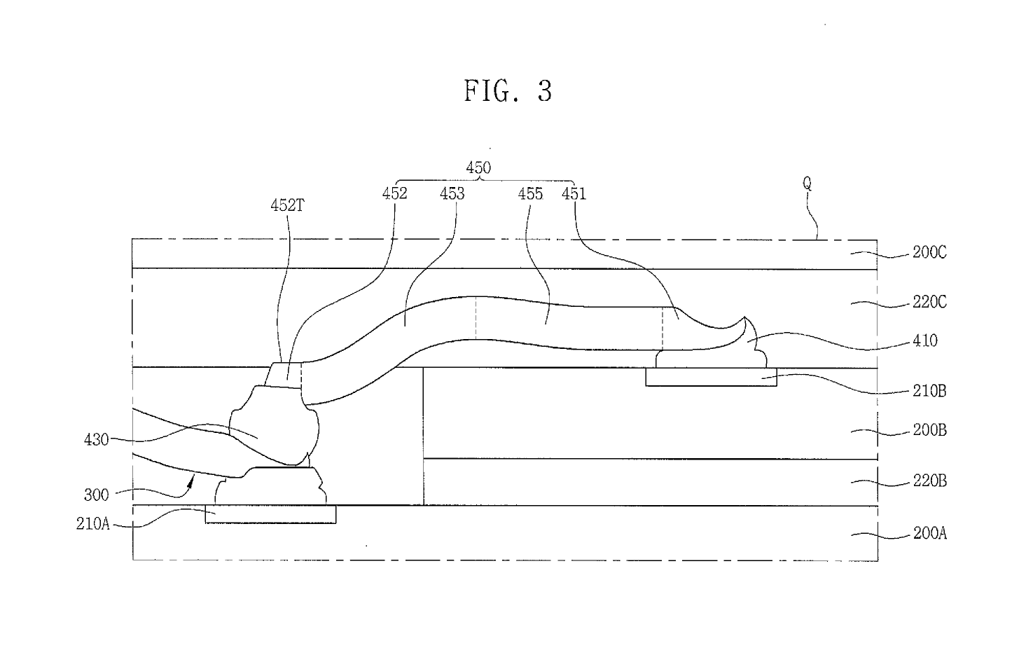

FIG. 3 is a partial view illustrating a first chip bonding structure of a semiconductor package in accordance with an embodiment of the inventive concept. Referring to FIG. 3, the first chip bonding structure of the semiconductor package in accordance with the present embodiment of the inventive concept may include, for example, a first chip coupling bump 410, a first chip coupling ball 430, and a first chip connection wire 450. The first chip connection wire 450 may include, for example, a first chip coupling stitch part 451, a first chip coupling neck part 452, a first chip connection curve part 453, and a first chip connection middle part 456. The first chip connection curve part 453 may have, for example, a logistic curve shape.

An upper surface of the first chip coupling neck part 452 may be, for example, parallel to the upper surface of the second semiconductor chip 200B. The third adhesive layer 220C may, for example, cover the upper surface of the first chip coupling neck part 452. The upper surface of the first chip coupling neck part 452 may be, for example, in direct contact with the third adhesive layer 220C. The upper surface of the first chip coupling neck part 452 may be located, for example, inside the third adhesive layer 220C.

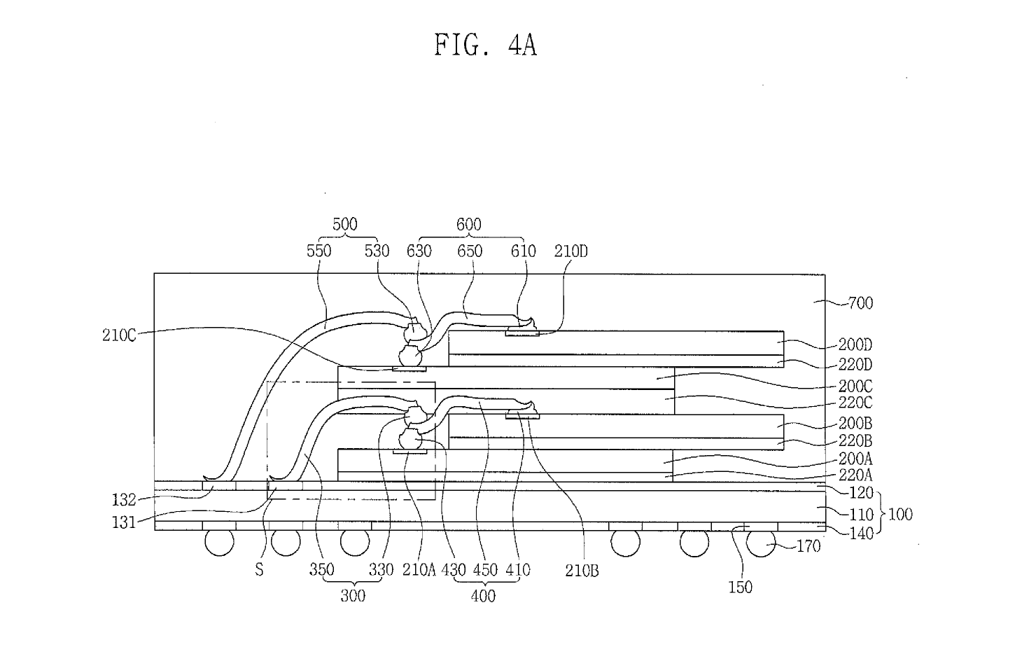

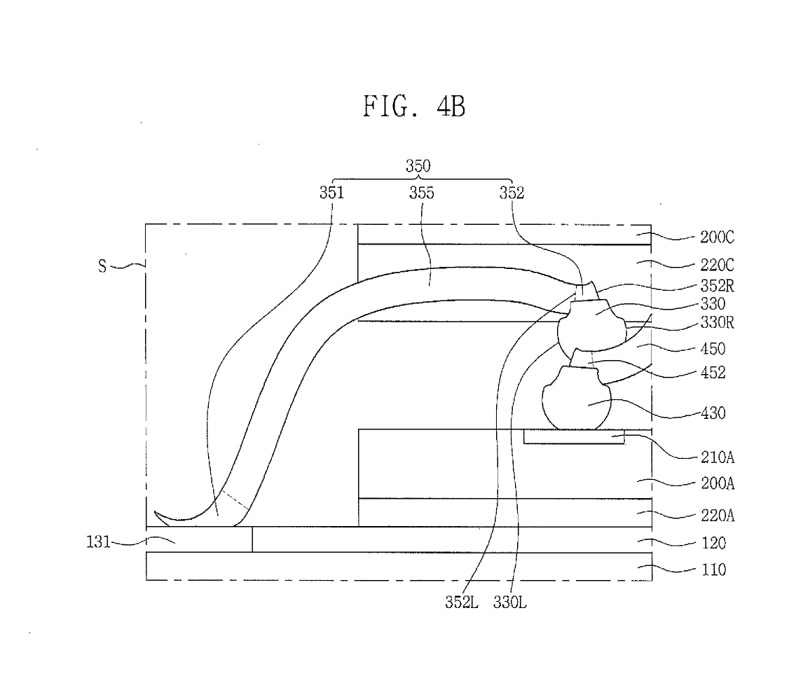

FIG. 4A is a cross-sectional view illustrating a semiconductor package in accordance with an embodiment of the inventive concept. FIG. 4B is an enlarged partial view of region S in FIG. 4A.

Referring to FIGS. 4A and 4B, a semiconductor package in accordance with an embodiment of the inventive concept may include, for example, a circuit board 100 including first and second board pads 131 and 132 located on the upper surface thereof, a first semiconductor chip 200A including a first chip pad 210A located on an upper surface thereof, a second semiconductor chip 200B including a second chip pad 210B located on an upper surface thereof, a third semiconductor chip 200C including a third chip pad 210C located on an upper surface thereof, a fourth semiconductor chip 200D including a fourth chip pad 210D located on an upper surface thereof, a first board bonding structure 300 connecting the first board pad 131 and the first chip pad 210A, a first chip bonding structure 400 connecting the first chip pad 210A and the second chip pad 210B, a second board bonding structure 500 connecting the second board pad 132 and the third chip pad 210C, a second chip bonding structure 600 connecting the third chip pad 210C and the fourth chip pad 210D, and a molding substance 700 covering the first to fourth semiconductor chips 200A to 200D, first and second board bonding structures 300 and 500, and first and second chip bonding structures 400 and 600.

The first semiconductor chip 200A may be mounted, for example, on the upper surface of the circuit board 100. The second semiconductor chip 200B may be, for example, offset-stacked on the upper surface of the first semiconductor chip 200A. The third semiconductor chip 200C may be, for example, offset-stacked on the upper surface of the second semiconductor chip 200B. The fourth semiconductor chip 200D may be, for example, offset-stacked on the upper surface of the third semiconductor chip 200C. The third semiconductor chip 200C may be, for example, vertically aligned with the first semiconductor chip 200A. The fourth semiconductor chip 200D may be, for example, vertically aligned with the second semiconductor chip 200B.

The first board bonding structure 300 may include, for example, a first board coupling ball 330 and a first board connection wire 350. The first board coupling ball 330 may be located, for example, on an upper surface of the first chip pad 210A. The first board connection wire 350 may, for example, connect the first board coupling ball 330 and the first board pad 131.

The first board coupling ball 330 may include, for example, a first side 330R and a second side 330L. The second side 330L of the first board coupling ball 330 may be, for example, opposite the first side 330R of the first board coupling ball 330. The first side 330R of the first board coupling ball 330 may, for example, head to the second semiconductor chip 200B. The first side 330R of the first board coupling ball 330 may, for example, face a left side of the second semiconductor chip 200B. The highest level of the first side 330R of the first board coupling ball 330 may be, for example, higher than the highest level of the second side 330L of the first board coupling ball 330.

The first board connection wire 350 may include, for example, a first board connection stitch part 351, a first board connection neck part 352, and a first board connection middle part 355. The first board connection stitch part 351 may be located, for example, on an upper surface of the first board pad 131. The first board connection neck part 352 may be located, for example, on an upper surface of the first board coupling ball 330. The first board connection middle part 355 may, for example, connect the first board connection stitch part 351 and the first board coupling ball 330.

The first board connection stitch part 351 may be, for example, in direct contact with the upper surface of the first board pad 131. The thickness of the first board connection stitch part 351 may, for example, become thinner as the distance from the first semiconductor chip 200A increases. The upper surface of the first board connection stitch part 351 may have, for example, a concave shape.

The first board connection neck part 352 may be, for example, in direct contact with the upper surface of the first board coupling ball 330. The first board connection neck part 352 may include, for example, a first side 352R and a second side 352L. The second side 352L of the first board connection neck part 352 may be, for example, opposite the first side 352R of the first board connection neck part 352. The second side 352L of the first board connection neck part 352 may, for example, head to the first board connection stitch part 351. The highest level of the first side 352R of the first board connection neck part 352 may be, for example, higher than the highest level of the second side 352L of the first board connection neck part 352.

The first board connection middle part 355 may be, for example, in direct contact with the second side 352L of the first board connection neck part 352. The first board connection middle part 355 may extend from, for example, second side 352L of the first board connection neck part 352. The first board connection middle part 355 may have, for example, a convex shape with respect to the upper surface of the circuit board 100.

The first chip bonding structure 400 may include, for example, a first chip coupling bump 410, a first chip coupling ball 430, and a first chip connection wire 450. The first chip coupling bump 410 may be, for example, in direct contact with an upper surface of the second chip pad 210B. The first chip coupling ball 430 may be located, for example, on the upper surface of the first chip pad 210A. The first chip connection wire 450 may, for example, connect the first chip coupling bump 410 and the first chip coupling ball 430.

The first chip connection wire 450 may include, for example, a first chip coupling neck part 452 in contact with the upper surface of the first chip coupling ball 430. The first chip connection wire 450 may extend, for example, from a side of the first chip coupling neck part 452, and include a region including a logistic curve shape.

The first chip coupling ball 430 may be, for example, in direct contact with the upper surface of the first chip pad 210A. The first chip coupling ball 430 may be located, for example, between the first chip pad 210A and the first board coupling ball 330. The first board coupling ball 330 may be located, for example, on an upper surface of the first chip connection wire 450. The first board coupling ball 330 may be, for example, in direct contact with an upper surface of the first chip coupling neck part 452.

The second board bonding structure 500 may include, for example, a second board coupling ball 530 and a second board connection wire 550. The second board coupling ball 530 may be located, for example, on an upper surface of the third chip pad 210C. The second board connection wire 550 may, for example, connect the second board pad 132 and the third chip pad 210C.

The second board coupling ball 530 may have, for example, the same shape as the first board coupling ball 330. The second board connection wire 550 may have, for example, a similar shape to the first board connection wire 350. For example, the second board connection wire 550 may have a convex curve shape with respect to the upper surface of the circuit board 100.

The second chip bonding structure 600 may include, for example, a second chip coupling bump 610, a second chip coupling ball 630, and a second chip connection wire 650. The second chip coupling bump 610 may be, for example, in direct contact with an upper surface of the fourth chip pad 210D. The second chip coupling bump 610 may have, for example, the same shape as the first chip coupling bump 410. The second chip coupling ball 630 may be, for example, in direct contact with the upper surface of the third chip pad 210C. The second chip coupling ball 630 may have, for example, the same shape as the first chip coupling ball 430. The second chip connection wire 650 may, for example, connect the second chip coupling bump 610 and the second chip coupling ball 630. The second chip connection wire 650 may have, for example, the same shape as the first chip connection wire 450. The second chip connection wire 650 may be located, for example, between the second chip coupling ball 630 and the second board coupling ball 530. The second board coupling ball 530 may be, for example, in direct contact with an upper surface of the second chip connection wire 650. A vertical distance between the lowest level and the highest level of the second chip bonding structure 600 may be, for example, the same as a vertical thickness between the lowest level and the highest level of the first chip bonding structure 400.

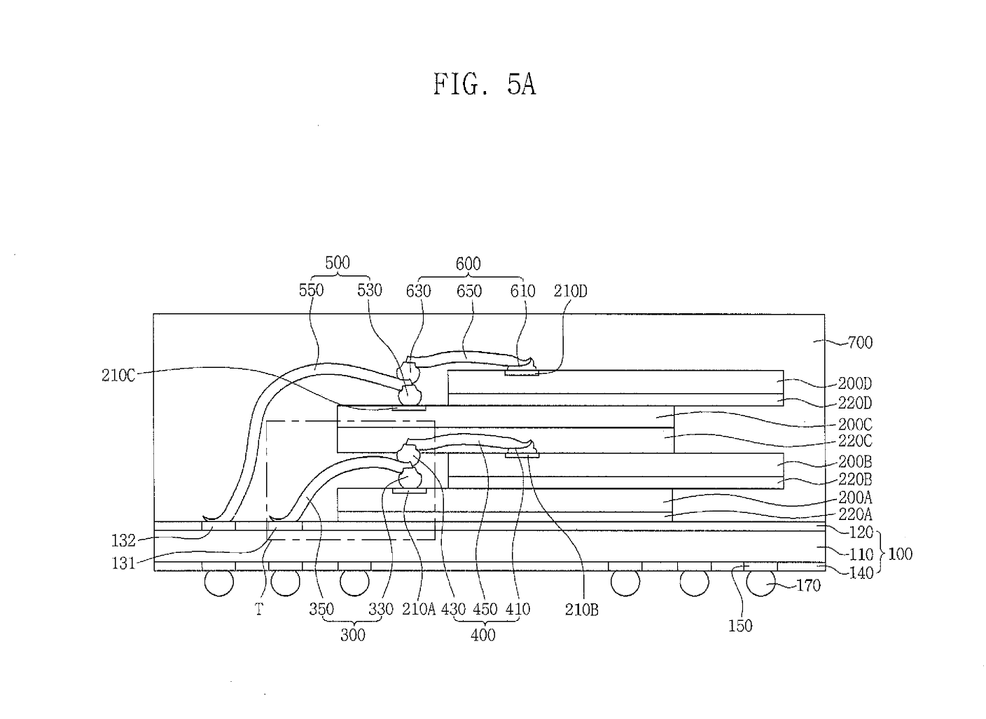

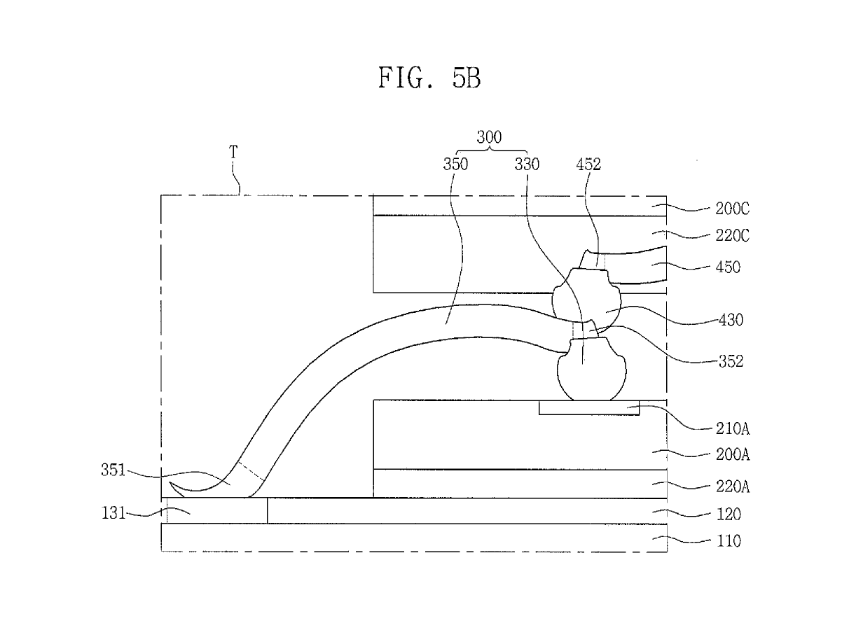

FIG. 5A is a cross-sectional view illustrating a semiconductor package in accordance with an embodiment of the inventive concept. FIG. 5B is an enlarged partial view of region T in FIG. 5A.

Referring to FIGS. 5A and 5B, a semiconductor package in accordance with an embodiment of the inventive concept may include, for example, a circuit board 100, semiconductor chips 200A to 200D offset-stacked on an upper surface of the circuit board 100, bonding structures 300 to 600 connecting the semiconductor chips 200A to 200D to the circuit board 100, and a molding substance 700 covering the semiconductor chips 200A to 200D and the bonding structures 300 to 600.

The bonding structures 300 to 600 may include, for example, a first board bonding structure 300 connecting a first board pad 131 and a first chip pad 210A, a first chip bonding structure 400 connecting the first chip pad 210A and a second chip pad 210B, a second board bonding structure 500 connecting the second board pad 132 and the third chip pad 210C, and a second chip bonding structure 600 connecting the third chip pad 210C and the fourth chip pad 210D.

The first board bonding structure 300 may include, for example, a first board coupling ball 330 in direct contact with an upper surface of the first chip pad 210A, and a first board connection wire 350 connecting the first board coupling ball 330 and the first board pad 131. The first board connection wire 350 may include, for example, a first board connection stitch part 351 in direct contact with an upper surface of the first board pad 131, and a first board connection neck part 352 in direct contact with an upper surface of the first board coupling ball 330. The first board connection wire 350 may have, for example, a convex curve shape with respect to the upper surface of the circuit board 100.

The first chip bonding structure 400 may include, for example, a first chip coupling bump 410 in direct contact with an upper surface the second chip pad 210B, a first chip coupling ball 430 in direct contact with an upper surface of the first board connection neck part 352 of the first board connection wire 350, and a first chip connection wire 450 connecting the first chip coupling bump 410 and the first chip coupling ball 430.

The upper surface of the first chip coupling ball 430 may be, for example, in contact with a third adhesive layer 220C. The first chip connection wire 450 may include, for example, a first chip coupling neck part 452 in direct contact with an upper surface of the first chip coupling ball 430. The first chip coupling neck part 452 may be located inside the third adhesive layer 220C. The first chip connection wire 450 may extend, for example, from a side of the first chip coupling neck part 452. The first chip connection wire 450 may be located, for example, inside the third adhesive layer 220C.

The second board bonding structure 500 may have, for example, the same shape as the first board bonding structure 300. For example, the second board bonding structure 500 may have a convex curve structure with respect to the upper surface of the circuit board 100.

The second chip bonding structure 600 may have, for example, the same shape as the first chip bonding structure 400. A vertical distance between the lowest level and the highest level of the second chip bonding structure 600 may be, for example, the same as the vertical distance between the lowest level and the highest level of the first chip bonding structure 400.

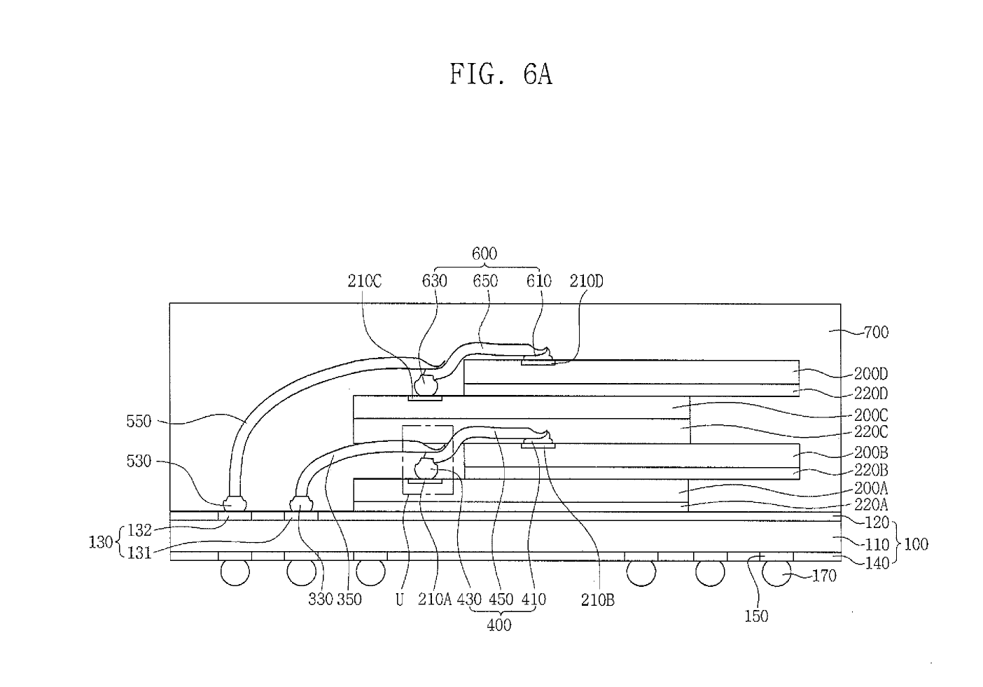

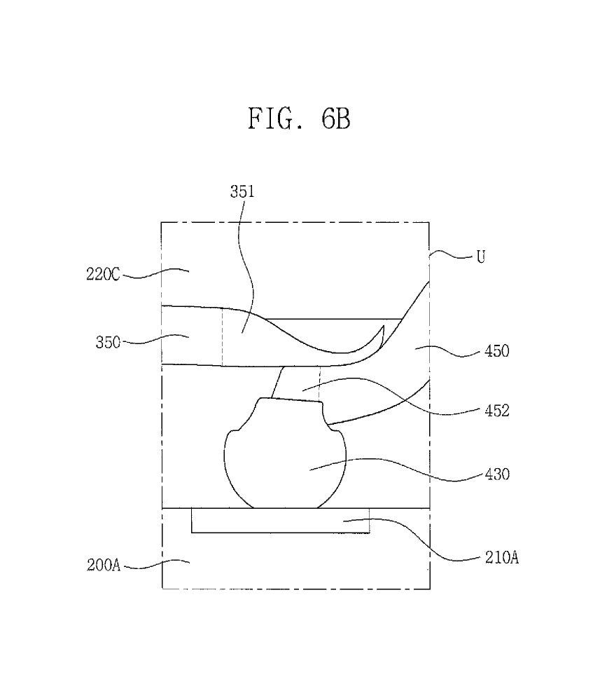

FIG. 6A is a cross-sectional view illustrating a semiconductor package in accordance with an embodiment of the inventive concept. FIG. 6B is an enlarged partial view of region U in FIG. 6A.

Referring to FIGS. 6A and 6B, a semiconductor package in accordance with an embodiment of the inventive concept may include, for example, a circuit board 100 including board pads 130, semiconductor chips 200A to 200D which are cross-stacked on an upper surface of the circuit board 100 and include chip pads 210A to 210D, board bonding structures 300 and 500 connecting the board pads 130 and the chip pads 210A to 210D, chip bonding structures 400 and 600 connecting the chip pads 210A to 210D, and a molding substance 700 covering the semiconductor chips 200A to 200D, board bonding structures 300 and 500, and chip bonding structures 400 and 600.

The board bonding structures 300 and 500 may include, for example, a first board bonding structure 300 connecting the first board pad 131 and the first chip pad 210A, and a second board bonding structure 500 connecting the second board pad 132 and the third chip pad 210C. The chip bonding structures 400 and 600 may include, for example, a first chip bonding structure 400 connecting the first chip pad 210A and the second chip pad 210B, and a second chip bonding structure 600 connecting the third chip pad 210C and the fourth chip pad 210D.

The first board bonding structure 300 may include, for example, a first board coupling ball 330 in direct contact with an upper surface of the first board pad 131, and a first board connection wire 350 connecting the first chip pad 210A and the first board coupling ball 330. The first board connection wire 350 may include, for example, a first board connection stitch part 351 located on an upper surface of the first chip pad 210A.

The first chip bonding structure 400 may include, for example, a first chip coupling bump 410 in direct contact with an upper surface of the second chip pad 210B, a first chip coupling ball 430 in direct contact with an upper surface of the first chip pad 210A, and a first chip connection wire 450 connecting the first chip coupling bump 410 and the first chip coupling ball 430.

The first chip connection wire 450 may include, for example, a first chip coupling neck part 452 in direct contact with an upper surface of the first chip coupling ball 430. An upper surface of the first chip coupling neck part 452 may be, for example, in direct contact with the first board connection stitch part 351. The first chip coupling ball 430 may be located, for example, between the first chip pad 210A and the first board connection wire 350.

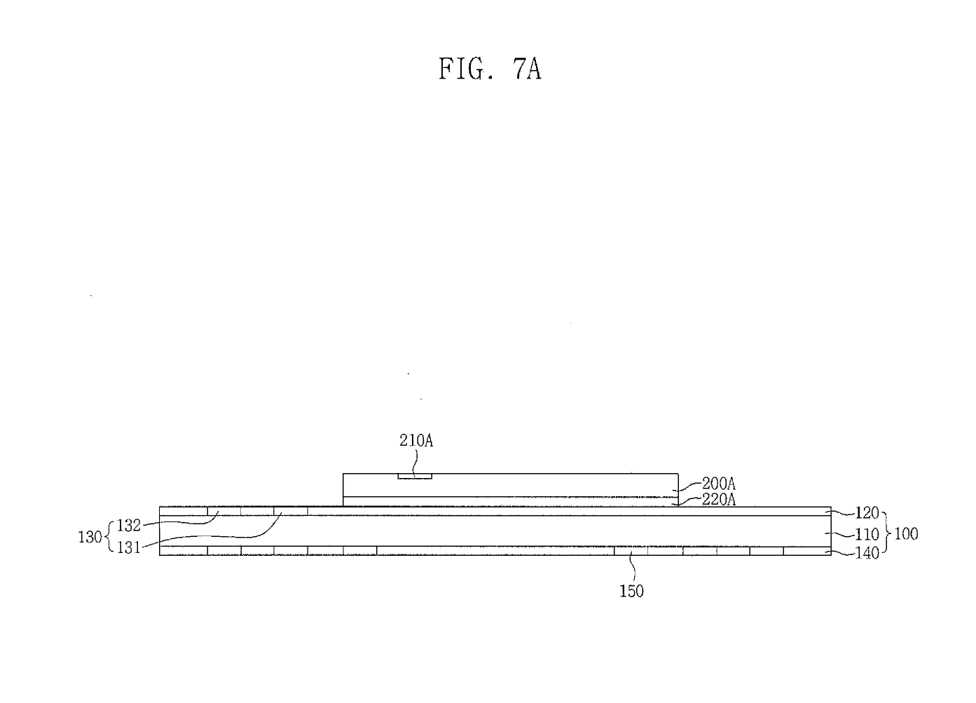

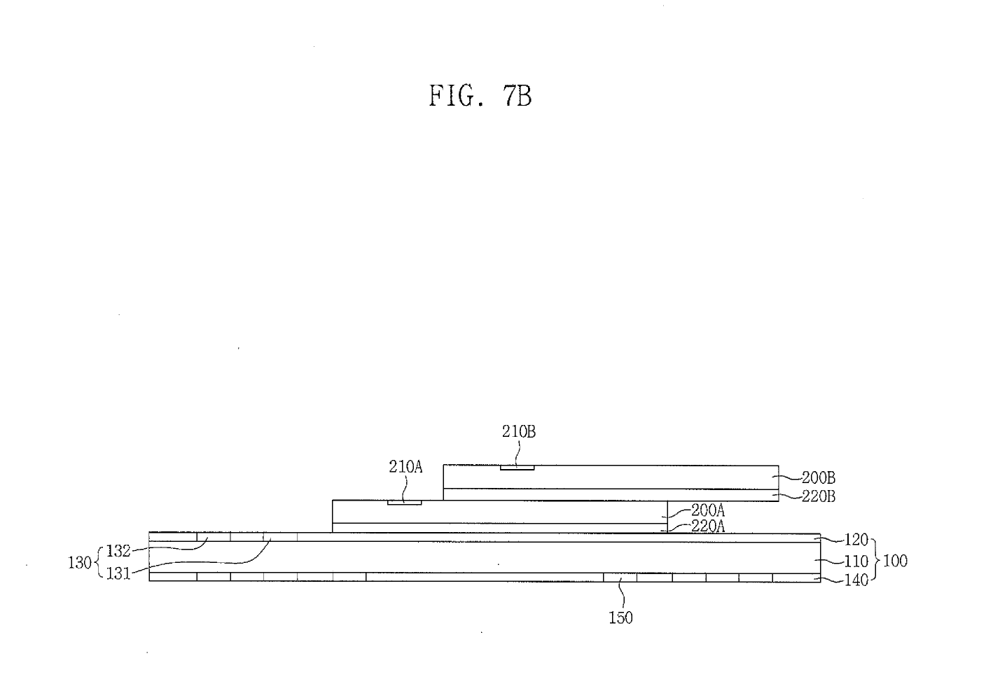

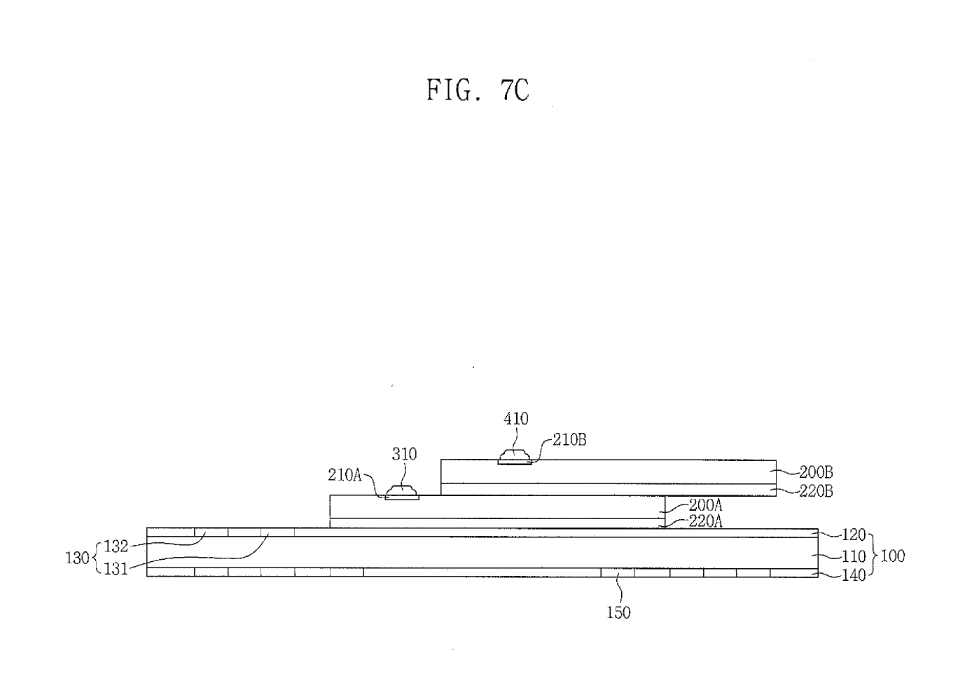

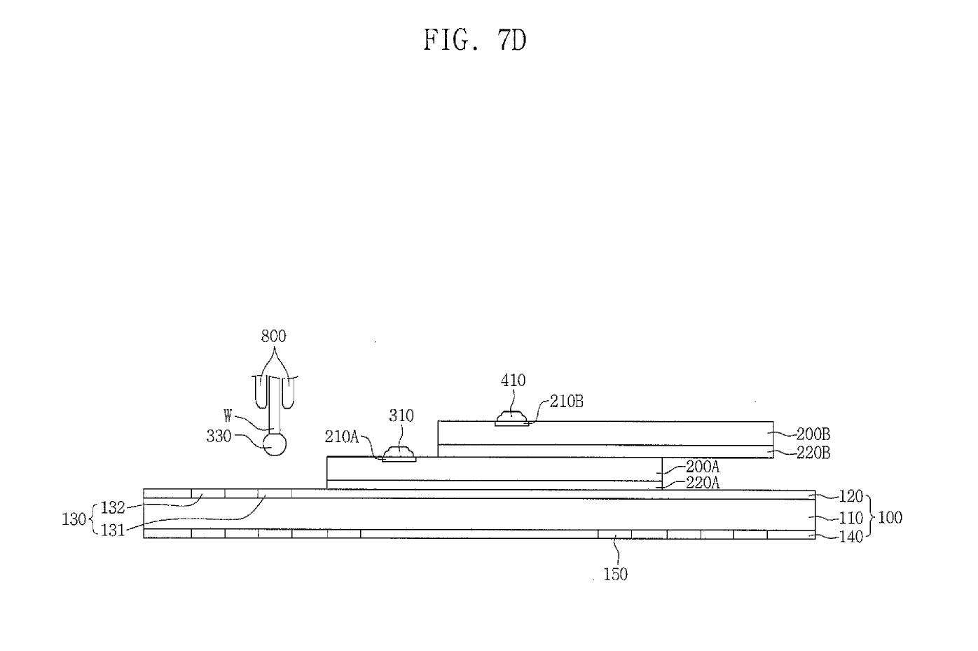

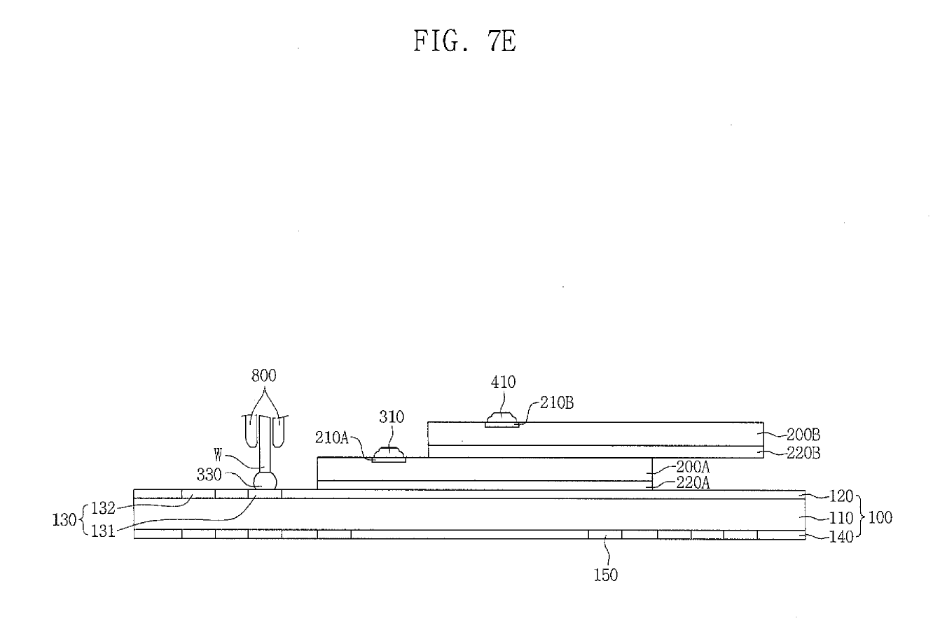

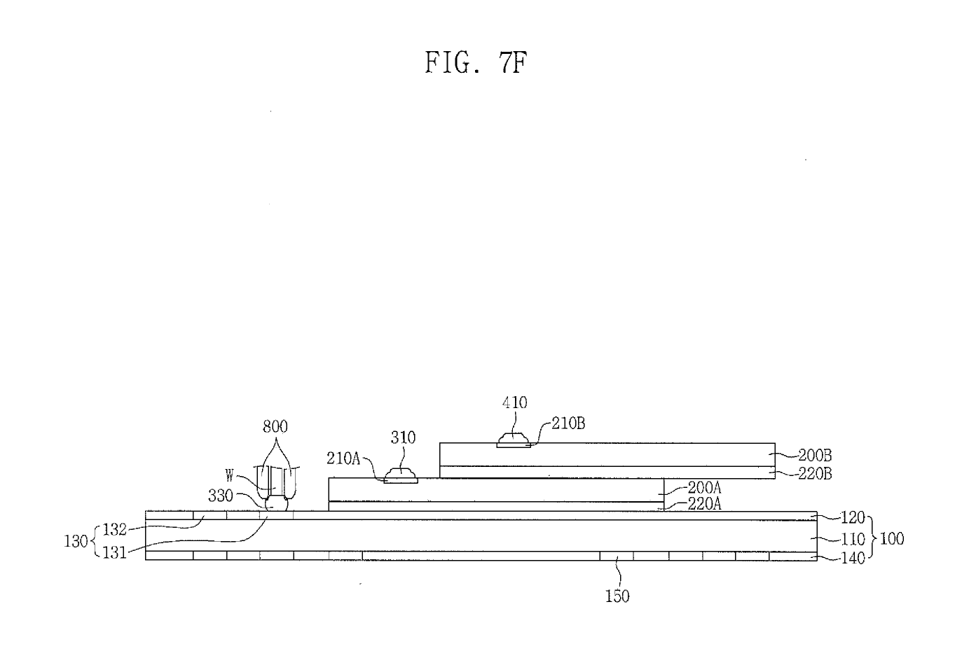

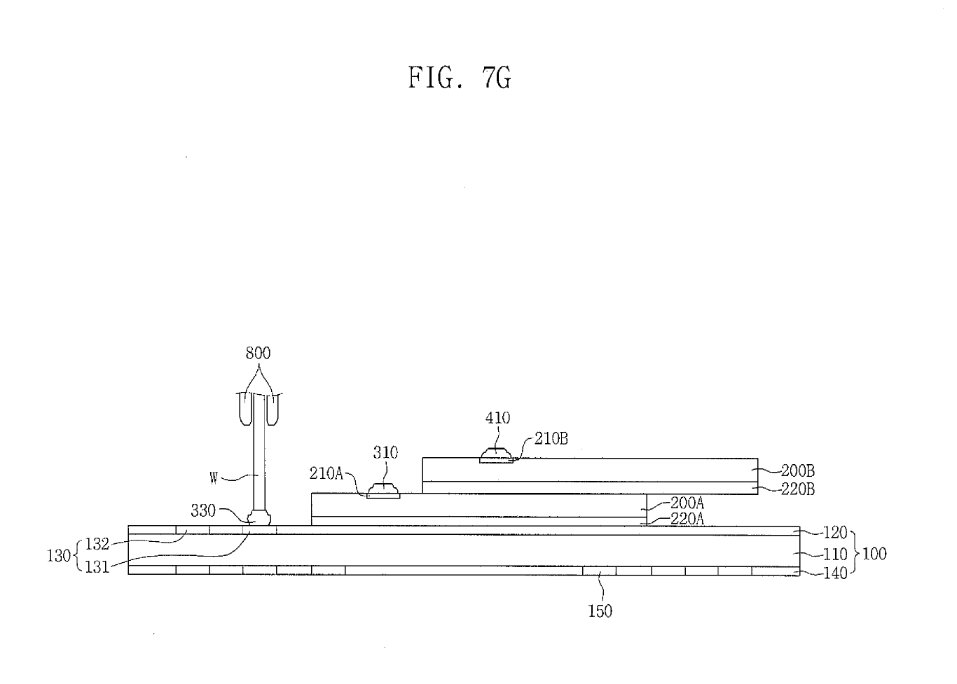

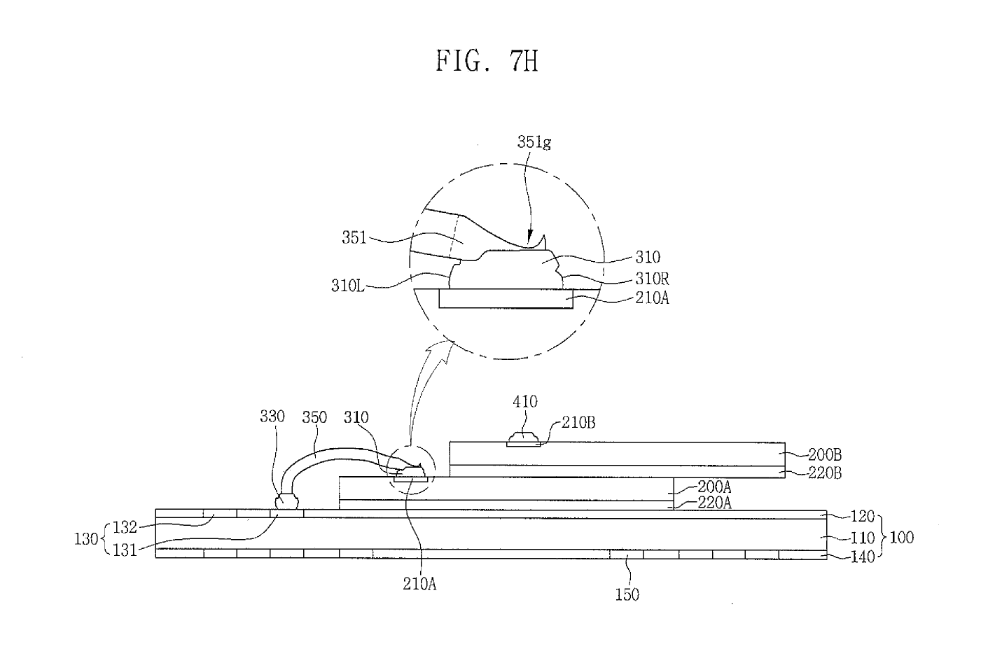

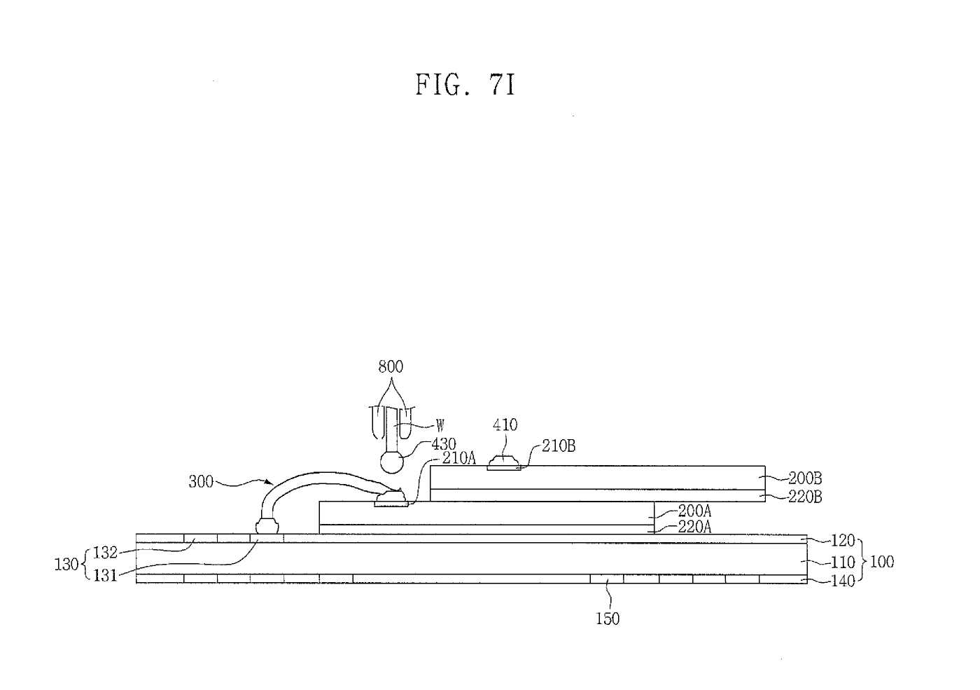

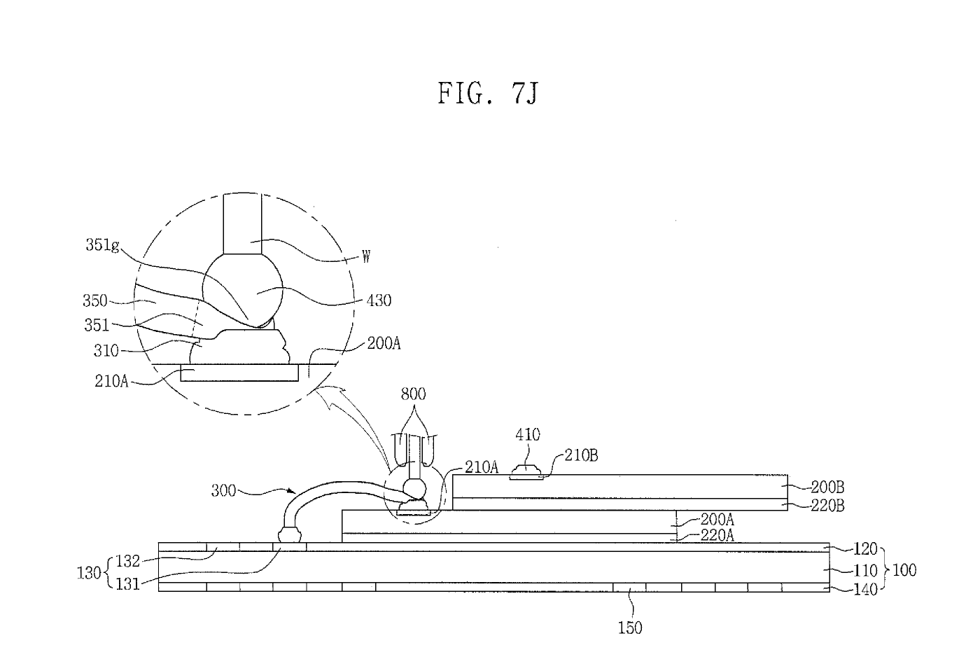

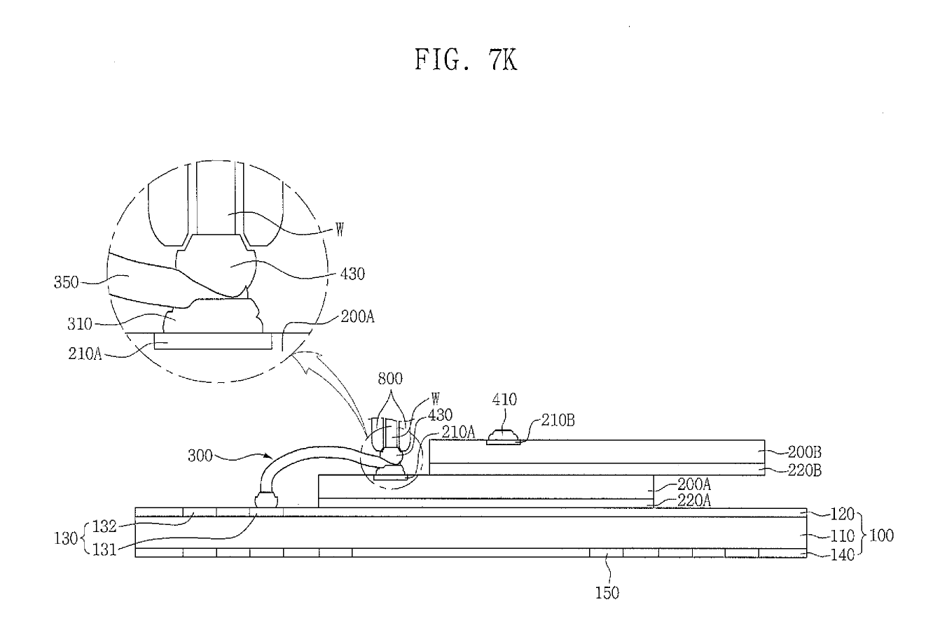

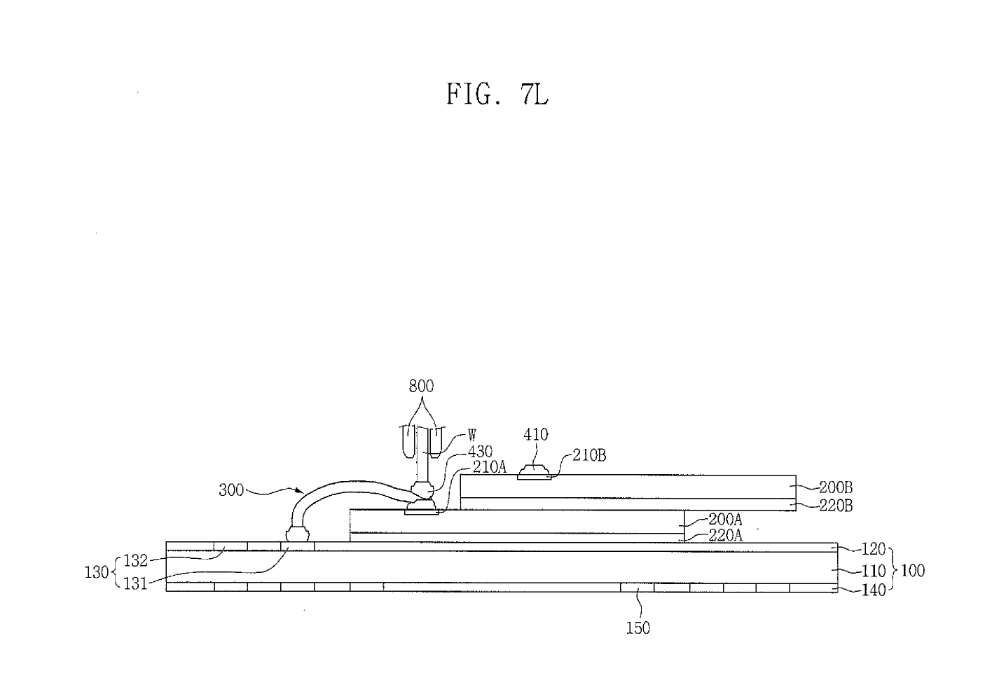

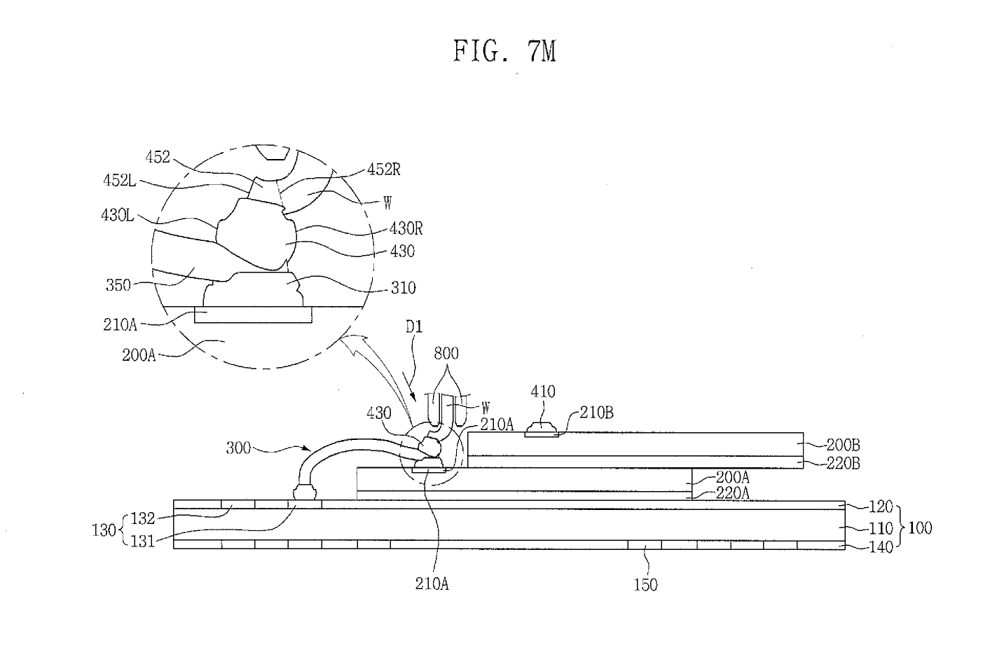

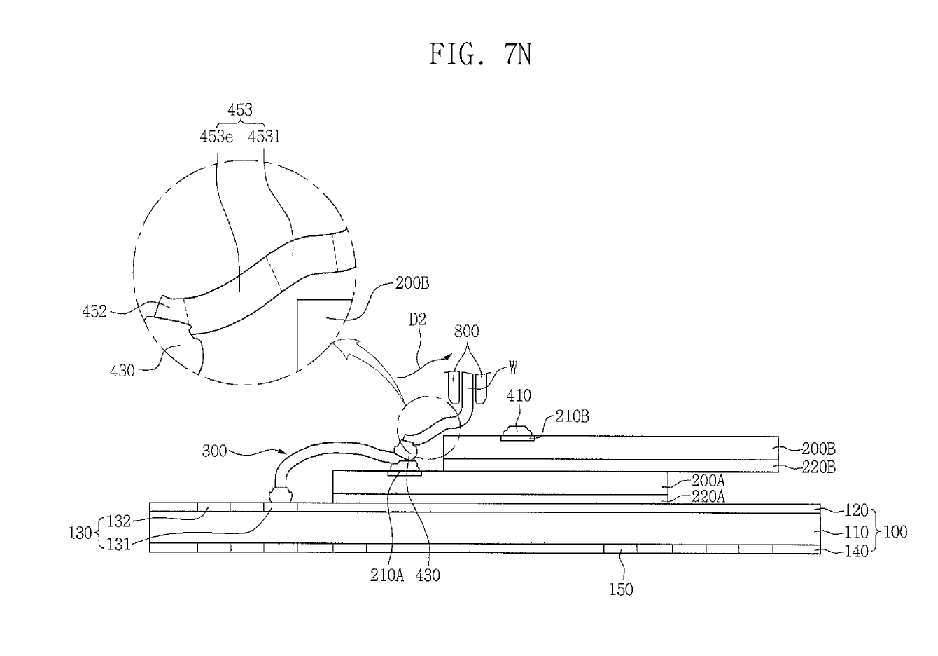

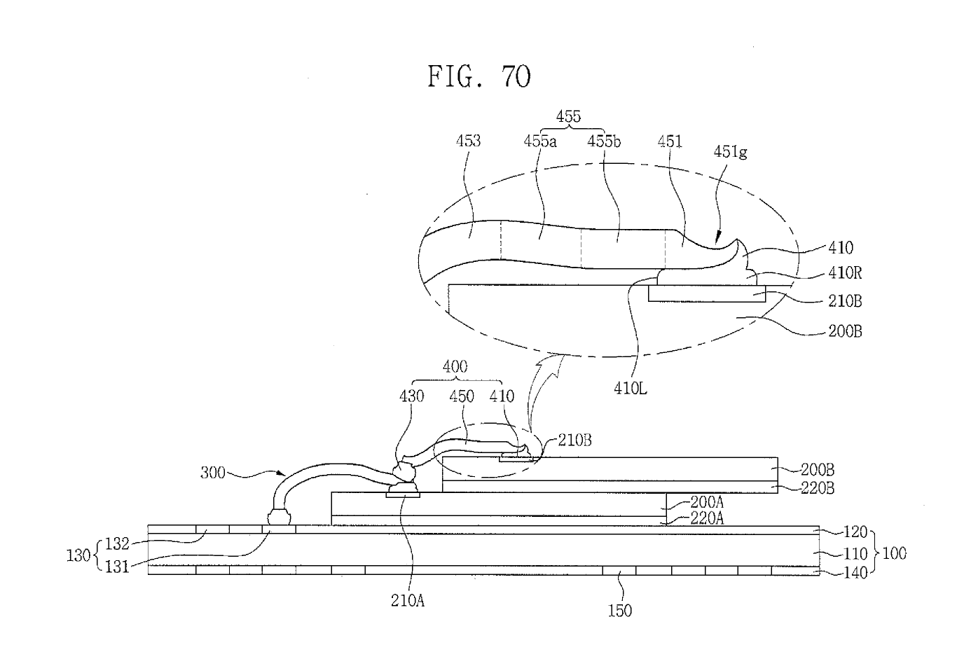

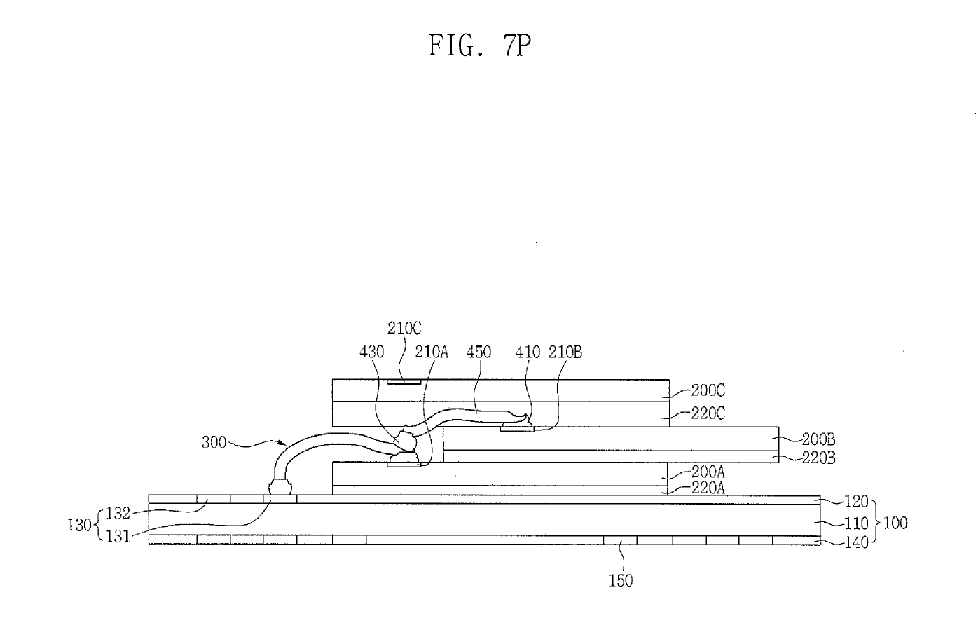

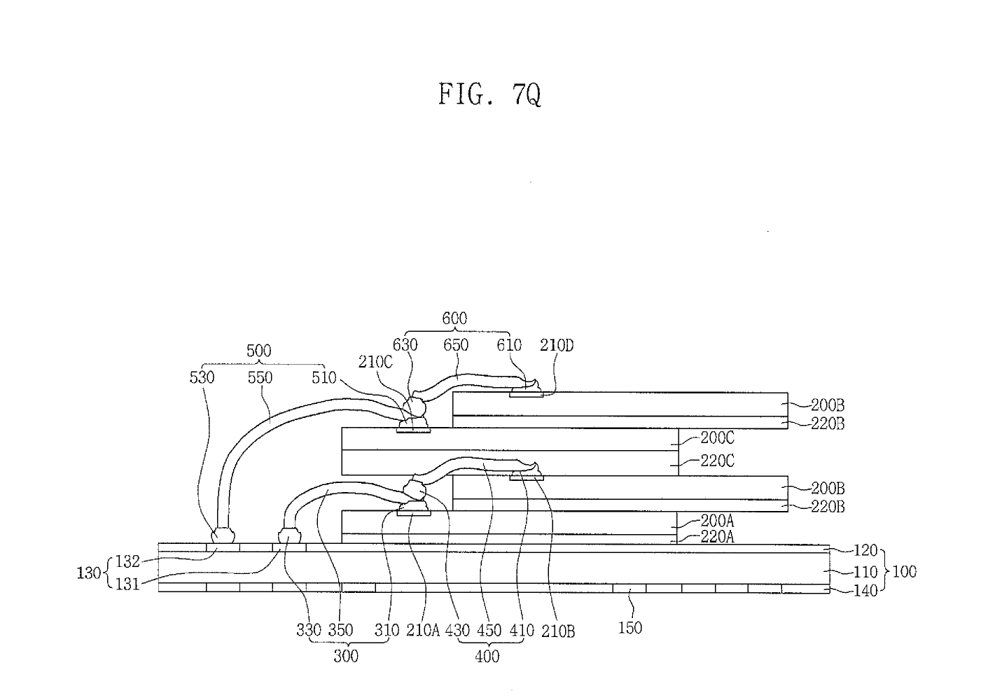

FIGS. 7A to 7R are cross-sectional views sequentially describing a method of fabricating a semiconductor package in accordance with an embodiment of the inventive concept.

A method of fabricating a semiconductor package in accordance with an embodiment of the inventive concept will be described with reference to FIGS. 1A to 1D and FIGS. 7A to 7R. The method of fabricating the semiconductor package in accordance with the embodiment of the inventive concept may include a process of mounting a first semiconductor chip 200A on an upper surface of the circuit board 100.

The process of mounting the first semiconductor chip 200A on the upper surface of the circuit board 100 may include, for example, a process of preparing the circuit board 100 including board pads 130 located on the upper surface thereof, a process of preparing the first semiconductor chip 200A including a first chip pad 210A located on an upper surface thereof, a process of aligning the first semiconductor chip 200A to the upper surface of the circuit board 100, and a process of attaching the first semiconductor chip 200A on the upper surface of the circuit board 100.

The process of aligning the first semiconductor chip 200A on the upper surface of the circuit board 100 may include, for example, a process of aligning the first semiconductor chip 200A on the upper surface of the circuit board 100 to not overlap the board pads 130. The board pads 130 may include, for example, a first board pad 131 and a second board pad 132.

The process of attaching the first semiconductor chip 200A to the upper surface of the circuit board 100 may include, for example, a process of attaching a first adhesive layer 220A on a lower surface of the first semiconductor chip 200A, and attaching the first semiconductor chip 200A on the upper surface of the circuit board 100 using the first adhesive layer 220A.

Referring to FIG. 7B, a method of fabricating a semiconductor package in accordance with an embodiment of the inventive concept may include a process of offset-stacking a second semiconductor chip 200B on the upper surface of the first semiconductor chip 200A.

The process of offset-stacking the second semiconductor chip on the upper surface of the first semiconductor chip 200A may include, for example, a process of preparing a second semiconductor chip 200B including a second chip pad 210B located on an upper surface thereof, a process of aligning the second semiconductor chip 200B on the upper surface of the first semiconductor chip 200A, and attaching the second semiconductor chip 200B to the upper surface of the first semiconductor chip 200A.

The process of aligning the second semiconductor chip 200B on the upper surface of the first semiconductor chip 200A may include, for example, a process of aligning the second semiconductor chip 200B on the upper surface of the first semiconductor chip 200A to expose a part of the upper surface of the first semiconductor chip 200A.

The process of aligning the second semiconductor chip 200B on the upper surface of the first semiconductor chip 200A to expose the part of the upper surface of the first semiconductor chip 200A, may include, for example, a process of aligning the second semiconductor chip 200B on the upper surface of the first semiconductor chip 200A to not overlap the first chip pad 210A.

The process of attaching the second semiconductor chip 200B to the upper surface of the first semiconductor chip 200A, may include, for example, a process of attaching the second adhesive layer 220B to a lower surface of the second semiconductor chip 200B, and a process of attaching the second semiconductor chip 200B on the upper surface of the first semiconductor chip 200A using the second adhesive layer 220B. The second adhesive layer 220B may have, for example, the same thickness as the first adhesive layer 220A. The second adhesive layer 220B may have, for example, the same physical properties as the first adhesive layer 220A.

Referring to FIG. 7C, a method of fabricating a semiconductor package in accordance with an embodiment of the inventive concept may include a process of forming a first board coupling bump 310 on an upper surface of the first chip pad 210A, and a process of forming a first chip coupling bump 410 on an upper surface of the second chip pad 210B.

The process of forming the first board coupling bump 310 on the upper surface of the first chip pad 210A and the process of forming the first chip coupling bump 410 on the upper surface of the second chip pad 210B may be, for example, simultaneously performed. The first chip coupling bump 410 may be formed to have, for example, the same shape as the first board coupling bump 310.

Referring to FIG. 7D, a method of fabricating a semiconductor package in accordance with an embodiment of the inventive concept may include a process of aligning the first board coupling ball 330 on an upper surface of the first board pad 131.

The process of aligning the first board coupling ball 330 on the upper surface of the first board pad 131 may include, for example, a process of installing a wire W to a capillary 800, a process of forming the first board coupling ball 330 in an end of the wire W, and moving the capillary 800 onto the upper surface of the first board pad 131.

The process of forming the first board coupling ball 330 in the end of the wire W may include, for example, a process of extending the wire W to an outside the capillary 800 and a process of forming the first board coupling ball 330 in the end of the wire W.

The process of forming the first board coupling ball 330 in the end of the wire W may include, for example, a process of attaching the first board coupling ball 330 in the end of the wire W.

Referring to FIG. 7E, a method of fabricating a semiconductor package in accordance with an embodiment of the inventive concept may include a process of attaching the first board coupling ball 330 on the upper surface of the first board pad 131.

The process of attaching the first board coupling ball 330 on the upper surface of the first board pad 131 may include, for example, a process of lowering the wire W in a vertical direction. The process of lowering the wire W in the vertical direction may include, for example, a process of fixing the wire W on the capillary 800 and a process of lowering the capillary 800 in the vertical direction.

Referring to FIG. 7F, a method of fabricating a semiconductor package in accordance with an embodiment of the inventive concept may include a process of compressing the first board coupling ball 330 on the upper surface of the first board pad 131.

The process of compressing the first board coupling ball 330 on the upper surface of the first board pad 131 may include, for example, a process of applying pressure to the first board coupling ball 330 in a vertical direction.

The process of applying pressure in a vertical direction to the first board coupling ball 330 may include, for example, a process of pressing the upper surface of the first board coupling ball 330 using the capillary 800.

Referring to FIG. 7G, a method of fabricating a semiconductor package in accordance with an embodiment of the inventive concept may include a process of extending the wire W in an upward direction of the first board coupling ball 330.

The process of extending the wire Win the upward direction of the first board coupling ball 330 may include, for example, a process of raising the capillary 800 installed with the wire in a vertical direction. The capillary 800 may, for example, rise higher than the upper surface of the second semiconductor chip 200B.

Referring to FIG. 7H, a method of fabricating a semiconductor package in accordance with an embodiment of the inventive concept may include a process of forming a first board connection wire 350 connecting the first board coupling bump 310 and the first board coupling ball 330. The first board coupling bump 310, the first board coupling ball 330, and the first board connection wire 350 may configure a first board bonding structure 300.

The process of forming the first board connection wire 350 may include, for example, a process of forming a first board connection stitch part 351 including a first board coupling stitch groove 351g on an upper surface of the first board coupling bump 310.

The process of forming the first board connection stitch part 351 including the first board coupling stitch groove 351g on the upper surface of the first board coupling bump 310 may include, for example, a process of stitch-bonding the wire W on the upper surface of the first board coupling bump 310.

The process of stitch-bonding the wire W on the upper surface of the first board coupling bump 310 may include, for example, a process of lowering the capillary 800 in a direction of the upper surface of the first board coupling bump 310, a process of contacting the wire W to the upper surface of the first board coupling bump 310, compressing the wire W using the capillary 800 on the upper surface of the first board coupling bump 310, and a process of cutting the wire W.

A second side 310L of the first board coupling bump 310 may be, for example, squashed by the process of stitch-bonding the wire W on the upper surface of the first board coupling bump 310. The second side 310L of the first board coupling bump 310 may, for example, head to the first board coupling ball 330. The highest level of the second side 310L of the first board coupling bump 310 may, for example, become lower than the highest level of a first side 310R of the first board coupling bump 310 due to the process of forming the first board connection wire 350. The first side 310R of the first board coupling bump 310 may be, for example, opposite the second side 310L of the first board coupling bump 310.

Referring to FIG. 7I, a method of fabricating a semiconductor package in accordance with an embodiment of the inventive concept may include a process of aligning the first chip coupling ball 430 on the upper surface of the first chip pad 210A.

The process of aligning the first chip coupling ball 430 on the upper surface of the first chip pad 210A may include, for example, a process of installing the wire W to the capillary 800, a process of forming the first chip coupling ball 430 in the end of the wire W, and a process of moving the capillary 800 to the upper surface of the first chip pad 210A.

The process of forming the first chip coupling ball 430 in the end of the wire W may include, for example, extending the wire W to an outside the capillary 800 and forming the first chip coupling ball 430 in the end of the wire W.

The process of forming the first chip coupling ball 430 in the end of the wire W may include may include, for example, a process of attaching the first chip coupling ball 430 to the end of the wire W.

Referring to FIG. 7J, a method of fabricating a semiconductor package in accordance with an embodiment of the inventive concept may include a process of attaching the first chip coupling ball 430 to an upper surface of the first board connection stitch part 351.

The process of attaching the first chip coupling ball 430 to the upper surface of the first board connection stitch part 351 may include, for example, a process of lowering the wire W in a vertical direction. The process of lowering the wire W in a vertical direction may include, for example, fixing the wire W on the capillary 800 and lowering the capillary 800 in a vertical direction. The first chip coupling ball 430 may be located, for example, inside the first board coupling stitch groove 351g.

Referring to FIG. 7K, a method of fabricating a semiconductor package in accordance with an embodiment of the inventive concept may include a process of compressing the first chip coupling ball 430 on the upper surface of the first board connection stitch part 351.

The process of compressing the first chip coupling ball 430 on the upper surface of the first board connection stitch part 351 may include, for example, a process of applying pressure in a vertical direction to the first chip coupling ball 430.

The process of applying pressure in the vertical direction to the first chip coupling ball 430 may include, for example, a process of pressing the upper surface of first chip coupling ball 430 using the capillary 800. The first chip coupling ball 430 may, for example, fill the first board coupling stitch groove 351g by the process of applying pressure in a vertical direction to the first chip coupling ball 430.

Referring to FIG. 7L, a method of fabricating a semiconductor package in accordance with an embodiment of the inventive concept may include a process of extending the wire W in an upward direction of the first chip coupling ball 430.

The process of extending the wire W in an upward direction of the first chip coupling ball 430 may include, for example, raising the capillary 800 installed with the wire W, in a vertical direction.

Referring to FIG. 7M, a method of fabricating a semiconductor package in accordance with an embodiment of the inventive concept may include a process of forming the first chip coupling neck part 452 on an upper surface of the first chip coupling ball 430.

The process of forming the first chip coupling neck part 452 may include, for example, a process of lowering the capillary 800 in a diagonal direction D1 toward a side of the second semiconductor chip 200B.

The process of lowering the capillary 800 in the diagonal direction D1 toward the side of the second semiconductor chip 200B may include, for example, a process of pressing the wire W in the diagonal direction D1 using the capillary 800. The highest level of a first side 452R of the first chip coupling neck part 452 may be, for example, lower than the highest level of a second side 452L of the first chip coupling neck part 452. The second side 452L of the first chip coupling neck part 452 may be, for example, opposite the first side 452R of the first chip coupling neck part 452. The first side 452R of the first chip coupling neck part 452 may face, for example, a side surface of the second semiconductor chip 200B.

A first side 430R of the first chip coupling ball 430 may be, for example, squashed due to the process of lowering the capillary 800 in the diagonal direction D1 toward the side of the second semiconductor chip 200B. The highest level of the first side 430R of the first chip coupling ball 430 may be, for example, lower than the highest level of a second side 430L of the first chip coupling ball 430. The second side 430L of the first chip coupling ball 430 may be, for example, opposite the first side 430R of the first chip coupling ball 430.

Referring to FIG. 7N, a method of fabricating a semiconductor package in accordance with an embodiment of the inventive concept may include a process of forming a first chip connection curve part 453 extending from the first side 452R of the first chip coupling neck part 452 toward the first chip coupling bump 410.

The process of forming the first chip connection curve part 453 may include, for example, a process of extending the wire W to the upper surface of the second semiconductor chip 200B. The process of extending the wire W to the upper surface of the second semiconductor chip 200B may include, for example, a process of raising the capillary 800 in a left upper direction D2 of the second semiconductor chip 200B.

The process of raising the capillary 800 in a left upper direction D2 of the second semiconductor chip 200B may include, for example, a process of gradually raising the capillary 800 as moving the capillary 800 toward the second semiconductor chip 200B, and a process of moving the capillary 800 along a left edge of the second semiconductor chip 200B.

Due to the process of gradually raising the capillary 800 as moving the capillary 800 toward the second semiconductor chip 200B, the wire W may be elongated in a curve shape of which a gradient increases as the distance from the first chip coupling neck part 452 increases. Due to the process of gradually raising the capillary 800 as moving the capillary 800 toward the second semiconductor chip 200B, the wire W may be elongated in a concave shape.

Due to the process of moving the capillary 800 along the left edge of the second semiconductor chip 200B, the wire W may be elongated in a curve shape of which a gradient decreases as the distance from the first chip coupling neck part 452 increases. Due to the process of moving the capillary 800 along the left edge of the second semiconductor chip 200B, the wire W may be elongated in a convex curve shape.

The process of gradually raising the capillary 800 as moving the capillary 800 toward the second semiconductor chip 200B and the process of moving the capillary 800 along the left edge of the second semiconductor chip 200B, may be, for example, sequentially performed. The process of forming the first chip connection curve part 453 may include, for example, a process of extending the wire W in a reverse curve shape. The process of forming the first chip connection curve part 453 may include, for example, a process of extending the wire W in a logistic curve shape.

Referring to FIG. 7O, a method of fabricating a semiconductor package in accordance with an embodiment of the inventive concept may include, for example, a process of forming a first chip connection wire 450 connecting the first chip coupling bump 410 and the first chip coupling ball 430. The first chip coupling bump 410, the first chip coupling ball 430, and the first chip connection wire 450 may configure a first chip bonding structure 400.

The process of forming the first chip connection wire 450 may include, for example, a process of forming a first chip connection middle part 455 extending from the first chip connection curve part 453 toward the first chip coupling bump 410, a process of forming a first chip coupling stitch part 451 including a first chip coupling stitch groove 451g on an upper surface of the first chip coupling bump 410.

The process of forming the first chip connection middle part 455 may include, for example, a process of moving the capillary 800 along the upper surface of the second semiconductor chip 200B. The process of forming the first chip connection middle part 455 may include, for example, a process of gradually lowering the capillary 800 as moving the capillary 800 toward the first chip coupling bump 410 and a process of moving the capillary 800 parallel to the upper surface of the second semiconductor chip 200B.

The process of gradually lowering the capillary 800 as moving the capillary 800 toward the first chip coupling bump 410 may include, for example, a process of extending the wire W in a falling curve shape falling in a direction from the first chip connection curve part 453 to the first chip coupling bump 410.

The process of moving the capillary 800 parallel to the upper surface of the second semiconductor chip 200B may include, for example, a process of extending the wire W in a direction parallel to the upper surface of the second semiconductor chip 200B. The process of gradually lowering the capillary 800 as moving the capillary 800 toward the first chip coupling bump 410 and a process of moving the capillary 800 parallel to the upper surface of the second semiconductor chip 200B may be, for example, sequentially performed.

The process of forming the first chip connection middle part 455 may include, for example, a process of forming a first middle region 455a which has a falling curve shape falling in the direction from the first chip connection curve part 453 to the first chip coupling bump 410, and a process of forming a second middle region 455b which has a linear shape parallel to the upper surface of the second semiconductor chip 200B. The first middle region 455a may, for example, extend from the first chip connection curve part 453. The second middle region 455b may, for example, extend in a direction from the first middle region 455a to the first chip coupling bump 410.

The process of forming the first chip coupling stitch part 451 including the first chip coupling stitch groove 451g on the upper surface of the first chip coupling bump 410 may include, for example, a process of stitch-bonding the wire W on the upper surface of the first chip coupling bump 410.

The process of stitch-bonding the wire W on the upper surface of the first chip coupling bump 410 may include, for example, a process of moving the capillary 800 to the upper surface of the first chip coupling bump 410, a process of contacting the wire W to the upper surface of the first chip coupling bump 410, a process of compressing the wire W using the capillary 800 on the upper surface of the first chip coupling bump 410, and a process of cutting the wire W.

The process of contacting the wire W to the upper surface of the first chip coupling bump 410 may include, for example, a process of pushing the first chip coupling bump 410 using the capillary 800. For example, the process of contacting the wire W on the upper surface of the first chip coupling bump 410 may include a process of pushing the upper surface of the first chip coupling bump 410 to the right direction using the capillary 800. The highest level of a second side 410L of the first chip coupling bump 410 may become, for example, lower than the highest level of a first side 410R of first chip coupling bump 410 due to the process of contacting the wire W to the upper surface of the first chip coupling bump 410. The second side 410L of the first chip coupling bump 410 may, for example, head to the first chip coupling ball 430. The first side 410R of the first chip coupling bump 410 may be, for example, opposite the second side 410L of the first chip coupling bump 410. The highest level of the second side 410L of the first chip coupling bump 410 may be, for example, the same as the lowest level of the second middle region 455b of the first chip connection middle part 455.

The upper surface of the first chip coupling bump 410 may have, for example, a different shape from the upper surface of the first board coupling bump 310 by the process of stitch-bonding the wire W to the upper surface of the first board coupling bump 310. For example, a vertical distance between the highest level of the first side 410R of the first chip coupling bump 410 and the highest level of the second side 410L of the first chip coupling bump 410 may be greater than a vertical distance between the highest level of the first side 310R of the first board coupling bump 310 and the highest level of the second side 310L of the first board coupling bump 310. A level difference of the upper surface of the first chip coupling bump 410 may be, for example, greater than a level difference of the upper surface of the first board coupling bump 310.

A method of fabricating a semiconductor package in accordance with an embodiment of the inventive concept may include forming the first chip coupling neck part 452 on the upper surface of the first chip coupling ball 430, and elongate the wire W from a side of the first chip coupling neck part 452. Accordingly, in the method of fabricating the semiconductor package in accordance with the embodiment of the inventive concept, the first chip connection curve part 453 of the first chip bonding structure 400 may be formed in a logistic curve shape. Accordingly, in a method of fabricating a semiconductor package in accordance with an embodiment of the inventive concept, a vertical distance between the lowest level and the highest level of the first chip bonding structure 400 may become smaller than the vertical distance between the lowest level and the highest level of the first board bonding structure 300. As a result, in a method of fabricating a semiconductor package in accordance with an embodiment of the inventive concept, the overall height of stacked semiconductor chips may be reduced, or relatively large number of semiconductor chips may be stacked.

Referring to FIG. 7P, a method of fabricating a semiconductor package in accordance with an embodiment of the inventive concept may include a process of cross-stacking a third semiconductor chip 200C on the upper surface of the second semiconductor chip 200B.

The process of cross-stacking the third semiconductor chip 200C on the upper surface of the second semiconductor chip 200B may include, for example, a process of preparing the third semiconductor chip 200C including a third chip pad 210C located on the upper surface thereof, a process of aligning the third semiconductor chip 200C on the upper surface of the second semiconductor chip 200B, and a process of attaching the third semiconductor chip 200C to the upper surface of the second semiconductor chip 200B.

The process of aligning the third semiconductor chip 200C on the upper surface of the second semiconductor chip 200B may include, for example, a process of aligning the third semiconductor chip 200C on the upper surface of the second semiconductor chip 200B to cover the second chip pad 210B. The process of aligning the third semiconductor chip 200C on the upper surface of the second semiconductor chip 200B to cover the second chip pad 210B may include, for example, a process of aligning the third semiconductor chip 200C on the upper surface of the second semiconductor chip 200B to be vertically aligned to the first semiconductor chip 200A.

The process of attaching the third semiconductor chip 200C to the upper surface of the second semiconductor chip 200B may include, for example, a process of attaching the third adhesive layer 220C to a lower surface of the third semiconductor chip 200C, and a process of attaching the third semiconductor chip 200C to the upper surface of the second semiconductor chip 200B using the third adhesive layer 220C.

The process of attaching the third semiconductor chip 200C to the upper surface of the second semiconductor chip 200B using the third adhesive layer 220C may include, for example, a process of inserting a portion of the first chip bonding structure 400 inside the third adhesive layer 220C. The portion of the first chip bonding structure 400 may be, for example, inserted into the third adhesive layer 220C by the process of attaching the third semiconductor chip 200C to the upper surface of the second semiconductor chip 200B.

The lower surface of the third semiconductor chip 200C may be, for example, spaced apart from the first chip bonding structure 400. The thickness of the third adhesive layer 220C may be, for example, greater than the thickness of the second adhesive layer 220B. The first chip bonding structure 400 may not be deformed by the process of attaching the third semiconductor chip 200C to the upper surface of the second semiconductor chip 200B. The third adhesive layer 220C may be, for example, softer than the second adhesive layer 220B. For example, the third adhesive layer 220C may have lower density than the second adhesive layer 220B.

Referring to FIG. 7Q, a method of fabricating a semiconductor package in accordance with an embodiment of the inventive concept may include a process of cross-stacking a fourth semiconductor chip 200D on the upper surface of the third semiconductor chip 200C, a process of forming a second board bonding structure 500, and a process of forming a second chip bonding structure 600.

The process of cross-stacking the fourth semiconductor chip 200D on the upper surface of the third semiconductor chip 200C may include, for example, a process of preparing a fourth semiconductor chip 200D including a fourth chip pad 210D located on an upper surface thereof, a process of aligning the fourth semiconductor chip 200D on the upper surface of the third semiconductor chip 200C, and a process of attaching the fourth semiconductor chip 200D to the upper surface of the third semiconductor chip 200C.

The process of aligning the fourth semiconductor chip 200D on the upper surface of the third semiconductor chip 200C may include, for example, a process of aligning the fourth semiconductor chip 200D on the upper surface of the third semiconductor chip 200C to cover the third chip pad 210C. The process of aligning the fourth semiconductor chip 200D on the upper surface of the third semiconductor chip 200C to cover the third chip pad 210C may include, for example, a process of aligning the fourth semiconductor chip 200D on the upper surface of the third semiconductor chip 200C to be vertically aligned on the second semiconductor chip 200B.

The process of attaching the fourth semiconductor chip 200D to the upper surface of the third semiconductor chip 200C may include, for example, a process of attaching the fourth adhesive layer 220D to the lower surface of the fourth semiconductor chip 200D, and a process of attaching the fourth semiconductor chip 200D to the upper surface of the third semiconductor chip 200C using the fourth adhesive layer 220D. The thickness of the fourth adhesive layer 220D may be, for example, the same as the thickness of the second adhesive layer 220B. Physical properties of the fourth adhesive layer 220D may be, for example, the same as the physical properties of the second adhesive layer 220B.

The process of forming the second board bonding structure 500 may include, for example, a process of forming a second board coupling bump 510 on the upper surface of the third chip pad 210C, a process of forming a second board coupling ball 530 on an upper surface of the second board pad 132 of the circuit board 100, and a process of forming a second board connection wire 550 connecting the second board coupling bump 510 and the second board coupling ball 530. The process of forming the second board bonding structure 500 may be, for example, the same as the process of forming the first board bonding structure 300.

The process of the second chip bonding structure 600 may include, for example, a process of forming a second chip coupling bump 610 on the upper surface of the fourth chip pad 210D, a process of forming a second chip coupling ball 630 on an upper surface of the second board coupling bump 510, and a process of forming a second chip connection wire 650 connecting the second chip coupling bump 610 and the second chip coupling ball 630. The process of forming the second chip bonding structure 600 may be, for example, the same as the process of forming the first chip bonding structure 400.

Referring to FIG. 7R, a method of fabricating a semiconductor package in accordance with an embodiment of the inventive concept may include a process of forming external terminals 170 on lower surfaces of the terminal pads 150 of the circuit board 100.

Referring to FIGS. 1A to 1D, a method of fabricating a semiconductor package in accordance with an embodiment of the inventive concept may include a process of forming a molding substance 700 on the upper surface of the circuit board 100.

The process of forming the molding substance 700 on the upper surface of the circuit board 100 may include, for example, a process of covering the first to fourth semiconductor chips 200A to 200D, the first and second board bonding structures 300 and 500, and the first and second chip bonding structures 400 and 600, with the molding substance 700. The upper surface of the circuit board 100 may be, for example, covered by the molding substance 700. Spaces between the first to fourth semiconductor chips 200A to 200D and the first and second board bonding structures 300 and 500, and spaces between the first to fourth semiconductor chips 200A to 200D and the first and second chip bonding structures 400 and 600, may be, for example, filled with the molding substance 700.

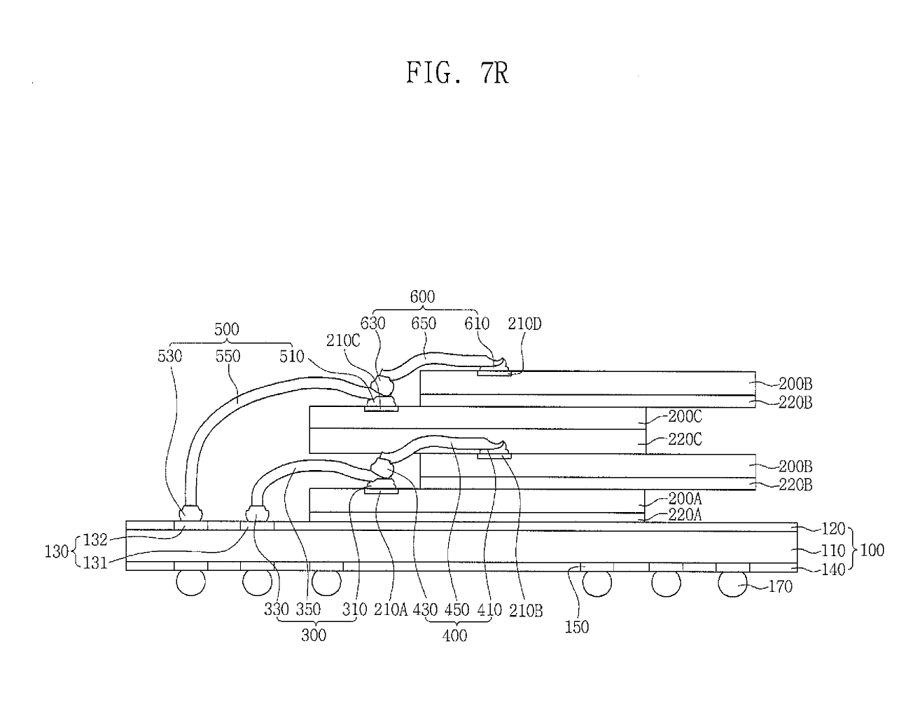

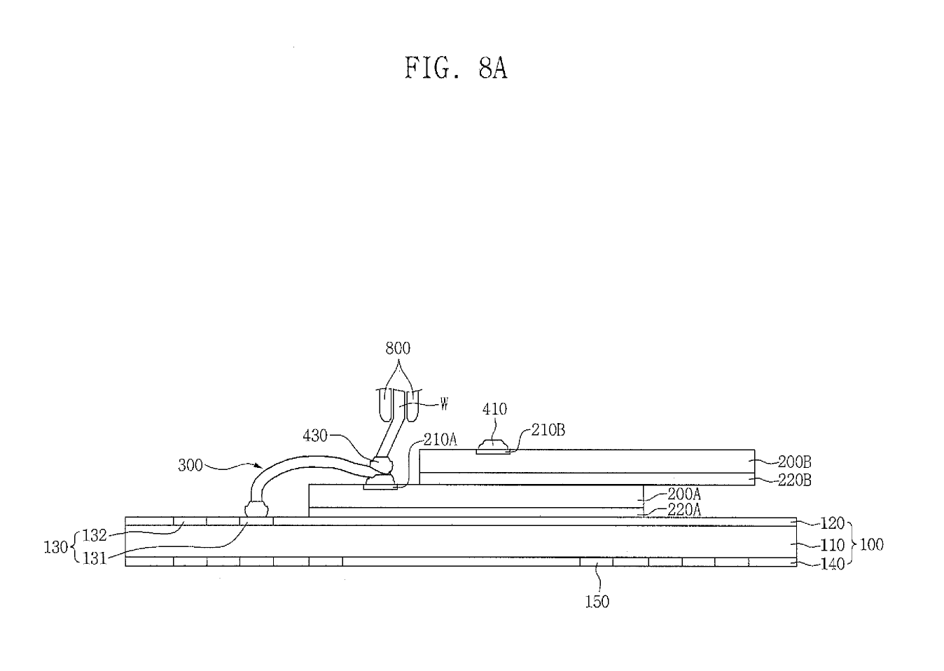

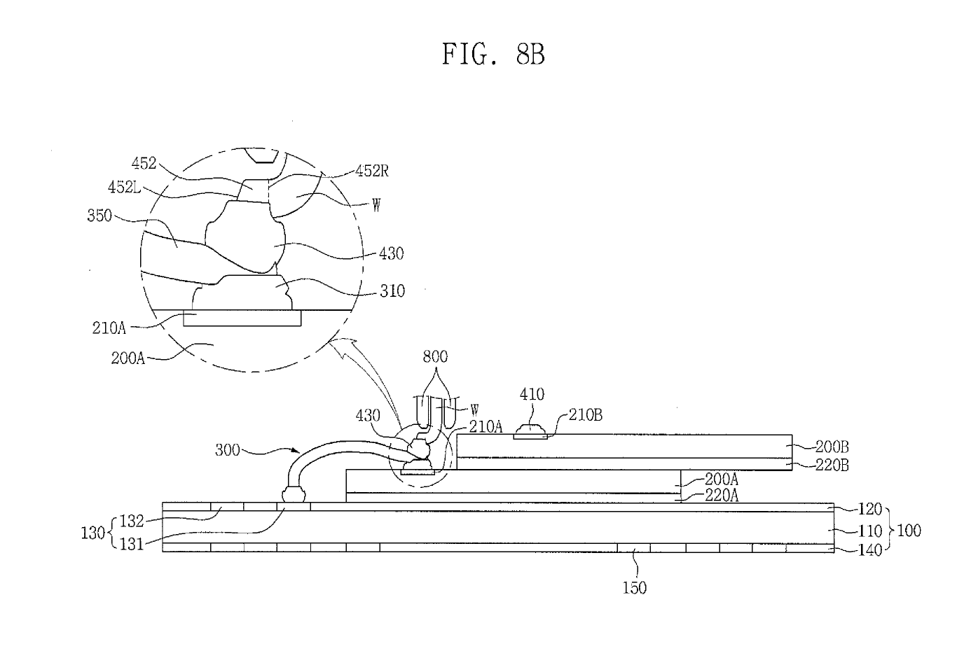

FIGS. 8A to 8C are cross-sectional views sequentially illustrating a method of fabricating a semiconductor package in accordance with an embodiment of the inventive concept.

The method of fabricating the semiconductor package in accordance with the embodiment of the inventive concept will be described with reference to FIGS. 1A, 3, and 8A to 8C. First, referring to FIG. 8A, a method of fabricating a semiconductor package in accordance with an embodiment of the inventive concept may include a process of mounting a first semiconductor chip 200A on an upper surface of a circuit board 100, a process of offset-stacking a second semiconductor chip 200B on an upper surface of the first semiconductor chip 200A, a process of forming a first board bonding structure 300 connecting a first board pad 131 of the circuit board 100 and a first chip pad 210A of the first semiconductor chip 200A, a process of forming a first chip coupling ball 430 on an upper surface of a first board connection stitch part 351 of the first board bonding structure 300, a process of extending the wire W toward an upper portion of the first chip coupling ball 430, and a process of moving a capillary 800 toward the second semiconductor chip 200B.

The process of moving the capillary 800 toward the second semiconductor chip 200B may include, for example, a process of fixing the wire W on the capillary 800 and a process of moving the capillary 800 in a right direction so that the left side of the capillary 800 is positioned on the upper surface of the first chip pad 210A.

Referring to FIG. 8B, a method of fabricating a semiconductor package in accordance with an embodiment of the inventive concept may include a process of forming a first chip coupling neck part 452 on the upper surface of the first chip coupling ball 430.

The process of forming the first chip coupling neck part 452 may include, for example, a process of lowering the capillary 800 in a vertical direction. The process of lowering the capillary 800 in a vertical direction may include, for example, a process of pressing a part of the wire W using the capillary 800. The highest level of a first side 452R of the first chip coupling neck part 452 may be, for example, the same as the highest level of the second side 452L of the first chip coupling neck part 452. An upper surface of the first chip coupling neck part 452 may be, for example, parallel to the upper surface of the first semiconductor chip 200A.

Referring to FIG. 8C, a method of fabricating a semiconductor package in accordance with an embodiment of the inventive concept may include a process of forming a second chip coupling ball 430 connecting the second chip coupling bump 410 and the second chip connection wire 450. The first chip coupling bump 410, the first chip coupling ball 430, and the first chip connection wire 450 may configure a first chip bonding structure 400.

The process of forming the first chip connection wire 450 may include, for example, a process of extending the wire W to an upper surface of the second semiconductor chip 200B, and a process of elongating the wire W along the upper surface of the second semiconductor chip 200B. The process of extending the wire W along the upper surface of the second semiconductor chip 200B may include, for example, a process of extending the wire W in a logistic curve shape. The process of forming the first chip connection wire 450 may include, for example, a process of forming a logistic curve-shaped first chip connection curve part 453 located near to the first chip coupling bump 430. The first chip connection curve part 453 may extend, for example, from the first side 452R of the first chip coupling neck part 452.

Referring to FIGS. 1A and 3, a method of fabricating a semiconductor package in accordance with an embodiment of the inventive concept may include, for example, a process of cross-stacking a third semiconductor chip 200C on the upper surface of the second semiconductor chip 200B, a process of cross-stacking a fourth semiconductor chip 200D on an upper surface of the third semiconductor chip, a process of forming a second board bonding structure 500, a process of forming a second chip bonding structure 600, a process of forming external terminals 170 on lower surfaces of terminal pads 150 of the circuit board 100, and a process of forming a molding substance 700 on the upper surface of the circuit board 100.

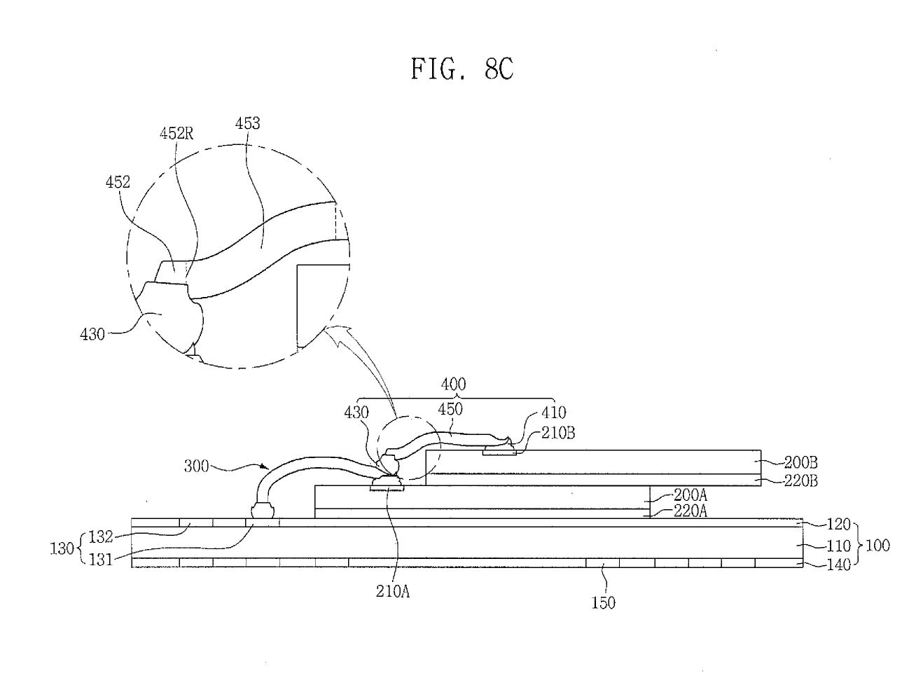

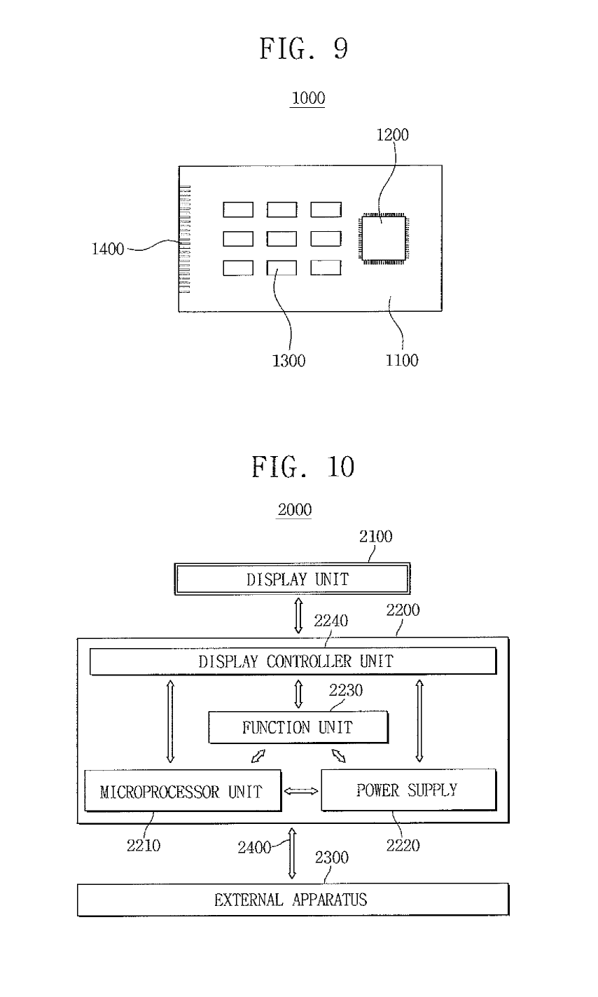

FIG. 9 is a configuration diagram illustrating a semiconductor module including a semiconductor package in accordance with an embodiment of the inventive concept.

Referring to FIG. 9, the semiconductor module 1000 may include, for example, a module substrate 1100, a memory 1200, a microprocessor 1300, and input/output terminals 1400. The memory 1200 and the microprocessor 1300 may be, for example, mounted on the module substrate 1100. The memory 1200 may include, for example, a semiconductor package in accordance with various embodiments of the inventive concept. Accordingly, it is possible to realize the semiconductor module 1000 including high density, high capacity, and a reduced size. The semiconductor module 1000 may include, for example, a memory card or a card package.

FIG. 10 is a configuration diagram illustrating an electronic apparatus including a semiconductor package in accordance with an embodiment of the inventive concept.

Referring to FIG. 10, the electronic apparatus 2000 may include, for example, a display unit 2100, a body 2200, and an external apparatus 2300. The body 2200 may be, for example, a system board or mother board including a printed circuit board (PCB). The body 2200 may include, for example, a microprocessor unit 2210, a power unit 2220, a function unit 2230, and a display controller unit 2240. The microprocessor unit 2210, the power supply 2220, the function unit 2230, and the display controller unit 2240 may be mounted or installed on the body 2200. The microprocessor unit 2210 may receive a voltage from the power supply 2220 to control the function unit 2230 and the display controller unit 2240. The power supply 2220 may receive a constant voltage from an external power source (not shown), etc., divide the voltage into various levels, and supply those voltages to the microprocessor unit 2210, the function unit 2230, and the display controller unit 2240. The function unit 2230 may perform various functions of the electronic systems 2000. For example, the function unit 2230 may have several components which can perform functions of the mobile phone such as dialing, video output to the display unit 2100 through communication with an external apparatus 2300, and sound output to a speaker, and if a camera is installed, the function unit 2230 may function as a camera image processor. The microprocessor unit 2210 and the function unit 2230 may include a semiconductor package in accordance with various embodiments of the inventive concept, in order to process various signals. Accordingly, it is possible to realize the electronic apparatus 2000 including high density, high capacity, and a reduced size. The display unit 2100 may be located, for example, on a surface of the body 2200. The display unit 2100 may be, for example, connected to the body 2200. The display unit 2100 may display an image processed by the display controller unit 2240 of the body 2200. The electronic apparatus 2000 may be, for example, connected to a memory card, etc. in order to expand capacity. In this case, the function unit 2230 may include a memory card controller. The function unit 2230 may exchange signals with the external unit 2300 through a wired or wireless communication unit 2400. In addition, the electronic apparatus 2000 may include, for example, a universal serial bus (USB) to expand functionality. In this case, the function unit 2230 may function as an interface controller.

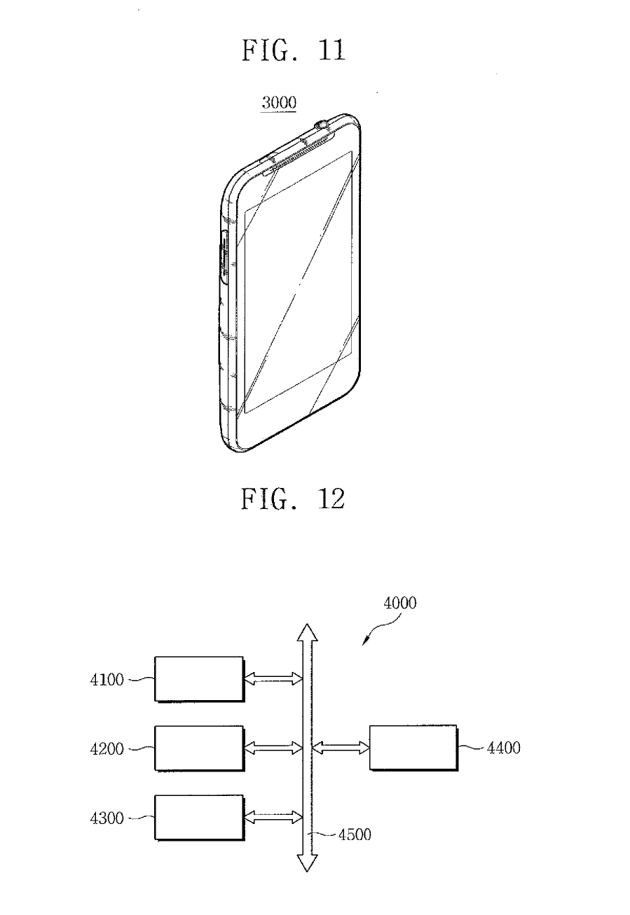

FIG. 11 is a configuration diagram illustrating a mobile apparatus including a semiconductor package in accordance with an embodiment of the inventive concept. Referring to FIG. 11, the mobile apparatus 3000 may be, for example, a mobile wireless phone. The mobile apparatus 3000 may be, for example, understood as a tablet PC. The mobile apparatus 3000 may include a semiconductor package in accordance with various embodiments of the inventive concept. Accordingly, it is possible to realize the mobile apparatus 3000 including high density, high capacity, and a reduced size.

FIG. 12 is a configuration diagram illustrating an electronic system including a semiconductor package in accordance with an embodiment of the inventive concept.

Referring to FIG. 12, the electronic system 4000 may include, for example, an interface 4100, a memory 4200, an input/output device 4300, and a controller 4400. The interface 4100 may be, for example, electrically connected to the memory 4200, the input/output device 4300, and the controller 4400 through a bus 4500. The interface 4100 may exchange data with an external system (not shown). The memory 4200 may include a semiconductor package in accordance with various embodiments of the inventive concept. Accordingly, it is possible to realize the memory 4200 including high density, high capacity, and a reduced size. The memory 4200 may store a command performed by the controller 4400 and/or the data. The controller 4400 may include a microprocessor, a digital processor, or a microcontroller. The electronic system 4000 may include, for example, a PDA, a portable computer, a web tablet, a wireless phone, a mobile phone, or a digital music player.

The semiconductor package in accordance with an embodiment of the inventive concept may lower a loop of a wire connecting two offset-stacked semiconductor chips. Accordingly, the semiconductor package in accordance with an embodiment of the inventive concept may reduce a vertical distance between the lowest level and the highest level of a chip bonding structure connecting the two offset-stacked semiconductor chips. Therefore, in the semiconductor package in accordance with an embodiment of the inventive concept, it is possible to realize the memory 4200 including high density, high capacity, and a reduced size.

Having described exemplary embodiments of the inventive concept, it is further noted that it is readily apparent to those of ordinary skill in the art that various modifications may be made without departing from the spirit and scope of the invention which is defined by the metes and bounds of the appended claims.

What is claimed is:

1. A semiconductor package, comprising:
a first semiconductor chip including a first chip pad disposed on an upper surface thereof;
a second semiconductor chip offset-stacked on the upper surface of the first semiconductor chip and including a second chip pad disposed on an upper surface thereof;
a chip coupling ball disposed on the first chip pad of the first semiconductor chip;
a chip coupling bump disposed on the second chip pad of the second semiconductor chip; and
a chip connection wire connecting the chip coupling ball with the chip coupling bump,
wherein the chip connection wire includes a chip connection curve part disposed near to the chip coupling ball, the chip connection curve part being a reverse curve shape.

2. The semiconductor package according to claim 1, wherein the chip connection curve part comprises a first curve region disposed near to the chip coupling ball, and a second curve region disposed near to the chip coupling bump,
wherein a gradient of the first curve region increases along a direction from the chip coupling ball toward the chip coupling bump, and a gradient of the second curve region decreases along the direction from the chip coupling ball toward the chip coupling bump.

3. The semiconductor package according to claim 2, wherein the chip connection wire further comprises a chip coupling neck part in contact with an upper surface of the chip coupling ball, the chip coupling neck part including a first side heading to the chip coupling bump and a second side opposite the first side, and the first curve region of the chip connection curve part is in contact with the first side of the chip coupling neck part.

4. The semiconductor package according to claim 3, wherein an upper surface of the chip coupling neck part has a concave shape.

5. The semiconductor package according to claim 1, wherein the chip coupling bump comprises a first side and a second side opposite the first side, the second side heading to the chip coupling ball, wherein a highest level of the first side of the chip coupling bump is higher than a highest level of the second side of the chip coupling bump.

6. The semiconductor package according to claim 5, wherein the chip connection wire further comprises a chip coupling stitch part in contact with an upper surface of the chip coupling bump, and a chip connection middle part disposed between the chip connection curve part and the chip coupling stitch part, wherein a thickness of the chip coupling stitch part decreases in a direction from the second side toward the first side of the chip coupling bump.

7. The semiconductor package according to claim 6, wherein the chip coupling stitch part comprises a chip coupling stitch groove disposed on an upper surface thereof.

8. The semiconductor package according to claim 7, wherein a lowest level of the chip coupling stitch groove is higher than the highest level of the second side of the chip coupling bump, and wherein the lowest level of the chip coupling stitch groove is lower than the highest level of the first side of the chip coupling bump.

9. The semiconductor package according to claim 6, wherein the chip connection middle part comprises a middle region parallel to the upper surface of the second semiconductor chip.

10. A semiconductor package, comprising:
a circuit board including a first board pad disposed on an upper surface thereof;
a first semiconductor chip mounted on the upper surface of the circuit board, the first semiconductor chip including a first chip pad disposed on an upper surface thereof;
a second semiconductor chip offset-stacked on the upper surface of the first semiconductor chip, the second semiconductor chip including a second chip pad disposed on an upper surface thereof;
a first board bonding structure connecting the first board pad and the first chip pad; and
a first chip bonding structure connecting the first chip pad and the second chip pad,
wherein a vertical distance between a lowest level and a highest level of the first chip bonding structure is smaller than a vertical distance between a lowest level and a highest level of the first board bonding structure.

11. The semiconductor package according to claim 10, wherein the first board bonding structure comprises a board coupling ball disposed on the first board pad, a board coupling bump disposed on the first chip pad, and a board connection wire connecting the board coupling ball and the board coupling bump,
wherein the first chip bonding structure comprises a chip coupling ball disposed on the first chip pad, a chip coupling bump disposed on the second chip pad, and a chip connection wire connecting the chip coupling ball and the chip coupling bump, and
wherein the board coupling bump is disposed between the first chip pad and the chip coupling ball.

12. The semiconductor package according to claim 11, wherein the chip connection wire comprises:
a chip coupling neck part in contact with an upper surface of the chip coupling ball;
a chip coupling stitch part in contact with an upper surface of the chip coupling bump;
a chip connection curve part disposed near to the chip coupling neck part; and
a chip connection middle part disposed between the chip connection curve part and the chip coupling stitch part,
wherein the chip connection curve part is a logistic curve shape.

13. The semiconductor package according to claim 11, wherein a height difference of the upper surface of the board coupling bump is smaller than a height difference of the chip coupling bump.

14. The semiconductor package according to claim 10, further comprising:
a third semiconductor chip offset-stacked on the upper surface of the second semiconductor chip, the third semiconductor chip including a third chip pad disposed on an upper surface thereof;
a fourth semiconductor chip offset-stacked on the upper surface of the third semiconductor chip, the fourth semiconductor chip including a fourth chip pad disposed on an upper surface thereof;
a second board bonding structure connecting the third chip pad to a second board pad of the circuit board; and
a second chip bonding structure connecting the third chip pad and the fourth chip pad,
wherein a vertical distance between a lowest level and a highest level of the second chip pad is the same as a vertical distance between the lowest level and the highest level of the first chip bonding structure.

15. The semiconductor package according to claim 14, wherein the third semiconductor chip is vertically aligned with the first semiconductor chip, and the fourth semiconductor chip is vertically aligned with the second semiconductor chip, wherein a vertical distance between the second semiconductor chip and the third semiconductor chip is greater than a vertical distance between the first semiconductor chip and the second semiconductor chip.

16. A method for fabricating a semiconductor package, comprising:
providing a circuit board including a first board pad disposed on an upper surface thereof;
mounting a first semiconductor chip on the upper surface of the circuit board such that the first semiconductor chip does not overlap with the first board pad, the first semiconductor chip including a first chip pad disposed on an upper surface thereof;
off-set stacking a second semiconductor chip on the upper surface of the first semiconductor chip such that a part of the upper surface of the first semiconductor chip is exposed and the second semiconductor chip does not overlap with the first chip pad, the second semiconductor chip including a second chip pad disposed on an upper surface thereof;
forming a first board coupling bump on the upper surface of the first chip pad and a first chip coupling bump on an upper surface of the second chip pad;
mounting the first board coupling ball on an upper surface of the first board pad;
forming a first board connection wire connecting the first board coupling bump and the first board coupling ball, wherein the first board connection wire includes a first board connection stitch part located on an upper surface of the first board coupling bump, wherein the first connection stitch part includes a groove located in an upper surface thereof;
mounting the first chip coupling ball on an upper surface of the first chip pad and in the groove of the first board connection stitch part;
forming a first chip coupling neck part on an upper surface of the first chip coupling ball;
forming a first chip connection curve part extending from a first side of the first coupling neck part toward the first chip coupling bump;
forming a first connection wire connecting the first chip coupling bump and the first chip coupling ball; and
forming a molding substance on an upper surface of the circuit board and covering the first semiconductor chip and the second semiconductor chip.

17. The method of claim 16, wherein the first board coupling bump and the first chip coupling bump are formed simultaneously.

18. The method of claim 16, wherein the mounting of the first board coupling ball on the upper surface of the first board pad comprises installing a wire to a capillary structure, forming the first board coupling ball on an end of the wire, aligning the capillary structure having the first board coupling ball on the end of the wire installed thereto with the upper surface of the first board pad, and moving the capillary structure onto the upper surface of the first board pad to mount the first board coupling ball on the upper surface of the first board pad.

19. The method of claim 16, wherein the mounting of the first semiconductor chip to the upper surface of the circuit board comprises attaching a first adhesive layer on a lower surface of the first semiconductor chip and attaching the first semiconductor chip on the upper surface of the circuit board using the first adhesive layer;

20. The method of claim 16, wherein the first chip coupling neck part is formed using a capillary structure having a wire attached thereto.
